(19) United States
(12) Patent Application Publication
(10) Pub. No.: US 2026/0321969 A1
(43) Pub. Date: Oct. 15, 2026

(54) SUBSTRATE MATERIAL FOR ANTENNA AND MANUFACTURING METHOD THEREFOR

(71) Applicant: Resonac Corporation, Tokyo (JP)

(72) Inventors: Arisa HATAKEYAMA, Tokyo (JP); Yasunori KAWABATA, Tokyo (JP); Kentaro FUJIEDA, Tokyo (JP); Masayoshi JOHMEN, Tokyo (JP); Ryosuke KIMURA, Tokyo (JP)

(73) Assignee: Resonac Corporation, Tokyo (JP)

(21) Appl. No.: 19/479,059

(22) PCT Filed: Oct. 30, 2024
(86) PCT No.: PCT/JP2024/038732

§ 371 Date: Oct. 27, 2025

(30) Foreign Application Priority Data
Jan. 31, 2024 (WO) PCT/JP2024/003168

(51) Int. Cl. H01Q 1/38; C08G 18/60; C08G 73/10; C08J 5/18; H01Q 1/22; H05K 1/03

(52) U.S. Cl. CPC H01Q 1/38; C08G 18/603; C08G 73/1046; C08J 5/18; H05K 1/0326; H05K 1/0346; H05K 1/036; H01Q 1/2283

(57) ABSTRACT

The present disclosure relates to an antenna substrate material containing a block copolymer, wherein the block copolymer contains a polyimide block (BI) and a polyamic acid block (BA).

### TECHNICAL FIELD

The present disclosure relates to an antenna substrate material, a method for manufacturing an antenna substrate material, and an antenna substrate material composition.

### BACKGROUND ART

The use of 5G (5th Generation Mobile Communication System) which enables simultaneous connections of large volumes of data with no delay continues to expand. Looking beyond to post-5G, in order to enable even higher operating frequencies, increases in the number of radio substations and enhanced functionality will be required. The radio units (RU) incorporated in radio substations employ an antenna such as a patch antenna for transmitting and receiving radio waves. A patch antenna has, for example, a multilayer substrate including an insulating substrate, and an antenna element mounted on the multilayer substrate (see Patent Document 1).

### PRIOR ART DOCUMENTS

### Patent Document

Patent Document 1: JP 2020-174114 A

### SUMMARY OF THE INVENTION

### Problems to be Solved by the Invention

In order to obtain favorable transmission characteristics, it is desirable that the organic material contained in the multilayer substrate has a low dielectric constant and a low coefficient of thermal expansion. The present disclosure provides an antenna substrate material that exhibits a low dielectric constant, a low dielectric loss tangent and a low coefficient of thermal expansion, and also provides an antenna substrate material composition, and a method for manufacturing an antenna substrate material.

### Means to Solve the Problems

The present invention includes the embodiments described below. However, the present invention is not limited to the following embodiments.

One embodiment relates to an antenna substrate material containing a block copolymer, wherein the block copolymer contains a polyimide block (BI) and a polyamic acid block (BA).

Another embodiment relates to an antenna substrate material containing a block copolymer, wherein the block copolymer contains a polyimide block (BI) and a polyamic acid block (BA), and contains a structural unit represented by formula (I) shown below and a structural unit represented by formula (A) shown below, wherein at least R^{A} described below and R^{C} described below are different, or at least R^{B} described below and R^{D} described below are different.

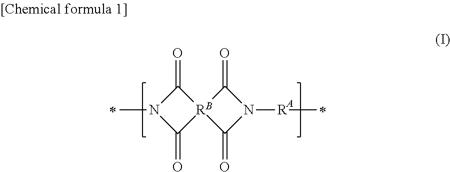

(In the formula, R^{A} and R^{B} each independently represent an organic group.)

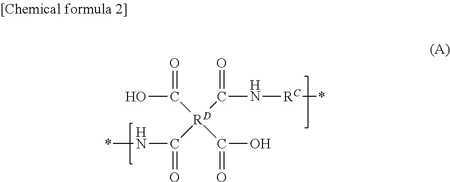

(In the formula, R^{C} and R^{D} each independently represent an organic group.)

Another embodiment relates to an antenna substrate material containing a block copolymer, wherein the block copolymer contains a polyimide block (BI) and a polyamic acid block (BA), and has a structure derived from a diamine or diisocyanate, and a structure derived from a tetracarboxylic dianhydride.

Another embodiment relates to a method for manufacturing an antenna substrate material containing a block copolymer, the method including: obtaining a polyimide (PI) using a diamine or diisocyanate and a tetracarboxylic dianhydride, obtaining a polyamic acid (PA) using a diamine and a tetracarboxylic dianhydride, and obtaining a block copolymer using the polyimide (PI) and the polyamic acid (PA).

Another embodiment relates to an antenna substrate material composition containing any one of the antenna substrate materials described above, and a solvent.

### Effects of the Invention

The present disclosure is able to provide an antenna substrate material that exhibits a low dielectric constant, a low dielectric loss tangent and a low coefficient of thermal expansion, as well as providing an antenna substrate material composition, and a method for manufacturing an antenna substrate material.

### BRIEF DESCRIPTION OF THE DRAWINGS

FIG. 1 is a schematic diagram illustrating one example of an antenna substrate.

FIG. 2 is a schematic diagram illustrating one example of an antenna substrate.

### EMBODIMENTS FOR CARRYING OUT THE INVENTION

Embodiments of the present invention are described below. However, the present invention is not limited to the embodiments described below. Further, the following embodiments can be implemented individually or in combination. Combinations of a plurality of embodiments are also included within the scope of the present invention.

In the present disclosure, in numerical ranges listed in a stepwise manner, the upper limit value or lower limit value from any particular numerical range may be substituted with the upper limit value or lower limit value from another numerical range. Further, the upper limit value or lower limit value from a numerical range disclosed in the present disclosure may be used to replace a value shown in an example. A numerical value may be selected from the upper limit numerical values and a numerical value selected from the lower limit numerical values listed in a stepwise manner in the present disclosure, and these selected values then used to form another stepwise numerical range. Furthermore, an upper limit numerical value and a lower limit numerical value disclosed in the present disclosure may be used to replace a value shown in an example.

In the present disclosure, each component may contain a plurality of types of the corresponding substance. In those cases where a plurality of substances corresponding with each component exist in a composition, the content or amount of each component, unless specifically stated otherwise, means the total content or amount of the plurality of substances that exist in the composition.

In the present disclosure, each structure within a polymer may include a plurality of types of that corresponding structure. In those cases where a plurality of types of corresponding structures exist for any of the structures within a polymer, the content or amount of that structure, unless specifically stated otherwise, means the total content or amount of the plurality of corresponding structures that exist within the polymer.

In the present disclosure, the term “layer” incorporates not only the case where, when the region in which the layer exists is observed, the layer is formed on the entirety of the region, but also the case where the layer is formed on only a portion of the region. This definition also applies for a “film”.

### <Antenna Substrate Material>

In a number of embodiments, the antenna substrate material contains a block copolymer containing a polyimide block (BI) and a polyamic acid block (BA). The antenna substrate material may also contain one or more optional components. The antenna substrate material is a material that is used for forming an antenna substrate. Examples of the antenna substrate include substrates for mounting an antenna element such as a patch antenna, and substrates for mounting an antenna device that incorporates an antenna element.

### <Block Copolymer>

The block copolymer contains a polyimide block (BI) and a polyamic acid block (BA). The block copolymer containing a polyimide block (BI) and a polyamic acid block (BA) includes an imide bond (also referred to as an “imide group”) and an amic acid bond (also referred to as a “amic acid structure” or “amic acid group”) within the polymer chain. The polyamic acid block (BA) may be a block which, as a result of a ring closing of the amic acid bond, forms a polyimide block (BI-A) that is different from the polyimide block (BI). The block copolymer may also contain another optional block that is different from the polyimide block (BI) and the polyamic acid block (BA). The block copolymer may contain either one type, or two or more types, of optional blocks.

In the present disclosure, a determination as to whether blocks are the same or different can be made on the basis of the structural unit(s) contained in the block. For example, if a structural unit exists that is included in one block but not included in the other block, then the two blocks are different. Examples of combinations of two different types of blocks include cases in which block 1 contains a structural unit 1, and block 2 contains a structural unit 2; cases in which block 1 contains the structural unit 1, and block 2 contains the structural unit 1 and the structural unit 2; and cases in which block 1 contains the structural unit 1 and the structural unit 2, and block 2 contains the structural unit 1 and a structural unit 3. The structural unit 1, structural unit 2 and structural unit 3 used in this explanation are mutually different structural units. In the present disclosure, the number of structural unit types included in each block is not limited to one or two types, and may also be three or more types. In the present disclosure, the number of types of blocks contained in the block copolymer is not limited to two, and may be three or more types.

Generally, it is thought that polyimides tend to exhibit a lower dielectric constant and a lower dielectric loss tangent as the free volume inside the molecule increases. The free volume can be increased by methods such as introducing a bulky group into the polyimide, providing a substituent in a suitable location for introducing a twisted structure into the skeleton, and providing a linking group such as an ether bond (oxy group), carbonyl bond (carbonyl group) or sulfonyl bond (sulfonyl group) in the skeleton for introducing a folded structure into the skeleton. On the other hand, it is thought that polyimides tend to exhibit a lower coefficient of thermal expansion as the molecule becomes more rigid. In those cases where the polyimide does not have the groups described above, but has a benzene ring structure or a biphenyl structure or the like, a more rigid molecule is obtained. Accordingly, achieving a combination of a low dielectric constant and low dielectric loss tangent, together with a low coefficient of thermal expansion is usually problematic. However, the present disclosure provides a material containing a block copolymer that is able to achieve this combination of properties. In the present disclosure, descriptions of observations or supposition in no way limit the present invention.

In a number of embodiments, the block copolymer contains a block having a large free volume, and a rigid block. For example, the polyimide block (BI) and the polyamic acid block (BA) may be a combination of blocks that includes a block containing a structural unit that increases the free volume of the polyimide and a block containing a structural unit that increases the amount of rigid structures contained in the polyimide. For example, the polyimide block (BI) and the polyamic acid block (BA) may be a combination of a block containing a structural unit that contains a non-aromatic hydrocarbon group or a structural unit that contains a linking group such as an oxy group or a carbonyl group in the skeleton or the like, and a block that either does not contain a structural unit that contains a non-aromatic hydrocarbon group or a structural unit that contains a linking group such as an oxy group or a carbonyl group in the skeleton, or contains the structural unit in a lesser amount that the above block. For example, the polyimide block (BI) and the polyamic acid block (BA) may be a combination of a block that exhibits a dielectric constant A, a dielectric loss tangent B and a coefficient of thermal expansion C, and a block that exhibits a dielectric constant a that is smaller than the above A, a dielectric loss tangent b that is smaller than the above B, and a coefficient of thermal expansion c that is larger than the above C. In the present disclosure, the polyimide obtained from the material containing the block copolymer has a low dielectric constant, a low dielectric loss tangent, and a low coefficient of thermal expansion.

### [Block Copolymer Containing Structural Unit (X)]

In a number of embodiments, the block copolymer contains the polyimide block (BI) and the polyamic acid block (BA), and contains a structural unit (X) having a group (X) containing at least one non-aromatic hydrocarbon group. In the present disclosure, the “group (X) containing at least one non-aromatic hydrocarbon group” is sometimes referred to as simply the “group (X)” or the “hydrocarbon group (X)”. In the present disclosure, the “structural unit (X) having a group (X) containing at least one non-aromatic hydrocarbon group” is sometimes referred to as simply the “structural unit (X)”. The hydrocarbon group (X) may be a group positioned between an imide group and an imide group, between an amic acid group and an amic acid group, or between an imide group and an amic acid group. The block copolymer may contain one type, or two or more types, of the hydrocarbon group (X). By including the hydrocarbon group (X) in the block copolymer, the polyimide tends to have a lower dielectric constant and a lower dielectric loss tangent.

The block copolymer may contain a structural unit other than the structural unit (X). Examples of structural units other than the structural unit (X) include a structural unit (Y) described below. The structural unit (Y) may be a structural unit having a group (Y) containing at least one aromatic cyclic group. In the present disclosure, the “group (Y) containing at least one aromatic cyclic group” is sometimes referred to as simply the “group (Y)” or the “organic group (Y)”. In the present disclosure, the “structural unit (Y) having a group (Y) containing at least one aromatic cyclic group” is sometimes referred to as simply the “structural unit (Y)”.

In those cases where the block copolymer contains the structural unit (X), only one of the polyimide block (BI) and the polyamic acid block (BA) may contain the structural unit (X), or both the polyimide block (BI) and the polyamic acid block (BA) may contain the structural unit (X). The polyimide block (BI) and the polyamic acid block (BA) may each, independently, contain one type, or two or more types, of the structural unit (X). For example, the block copolymer may contain a polyimide block (BI) containing the structural unit (X), and a polyamic acid block (BA) containing a different type of the structural unit (X).

In those cases where the block copolymer contains the structural unit (Y), only one of the polyimide block (BI) and the polyamic acid block (BA) may contain the structural unit (Y), or both the polyimide block (BI) and the polyamic acid block (BA) may contain the structural unit (Y). The polyimide block (BI) and the polyamic acid block (BA) may each, independently, contain one type, or two or more types, of the structural unit (Y). For example, the block copolymer may contain a polyimide block (BI) containing the structural unit (X) and a polyamic acid block (BA) containing the structural unit (Y), or may contain a polyimide block (BI) containing the structural unit (Y) and a polyamic acid block (BA) containing the structural unit (X).

### (Structural Unit (X))

The structural unit (X) contains at least the hydrocarbon group (X). The structural unit (X) may also contain at least one of an imide group and an amic acid group. The total number of carbon atoms within the “at least one non-aromatic hydrocarbon group” contained in the hydrocarbon group (X) is one or more. Carbon atoms contained within an imide group or amic acid group are not included in the total number of carbon atoms within the at least one non-aromatic hydrocarbon group in the hydrocarbon group (X). For example, the structural unit (X) may be a structural unit containing the hydrocarbon group (X), and an imide group or amic acid group. The block copolymer may contain the hydrocarbon group (X) within the structural unit (X), and an imide group or amic acid group within the polymer chain. The structural unit (X) may contain one type, or two or more types, of the hydrocarbon group (X). The structural unit (X) may also contain another optional group besides the hydrocarbon group (X), imide group and amic acid group. Examples of this optional group include organic groups such as the organic group (Y). In the present disclosure, the term “organic group” describes a group containing at least one carbon atom. The organic group (Y) may be a group positioned between an imide group and an imide group, between an amic acid group and an amic acid group, or between an imide group and an amic acid group. The block copolymer may contain the organic group (Y) within the polymer chain.

### (Hydrocarbon Group (X))

The hydrocarbon group (X) contains at least one non-aromatic hydrocarbon group. In the hydrocarbon group (X), the total number of carbon atoms within the at least one non-aromatic hydrocarbon group is one or more. In those cases where the hydrocarbon group (X) contains one non-aromatic hydrocarbon group, the total number of carbon atoms means the total number of all of the carbon atoms contained in that single non-aromatic hydrocarbon group. In those cases where the hydrocarbon group (X) contains two or more non-aromatic hydrocarbon groups, the total number of carbon atoms means the total number of all of the carbon atoms contained in those two or more non-aromatic hydrocarbon groups. In those cases where the hydrocarbon group (X) contains two or more non-aromatic hydrocarbon groups, the two or more non-aromatic hydrocarbon groups may be the same or different. The hydrocarbon group (X) may also contain another optional group besides the non-aromatic hydrocarbon group. The hydrocarbon group (X) is, for example, a monovalent to tetravalent group. The structural unit (X) preferably contains a divalent to tetravalent hydrocarbon group (X), more preferably contains a divalent or tetravalent hydrocarbon group (X), and even more preferably contains a divalent hydrocarbon group (X).

The non-aromatic hydrocarbon group is a hydrocarbon group that is non-aromatic and contains no aromatic rings. Examples of the at least one non-aromatic hydrocarbon group include saturated aliphatic hydrocarbon groups, unsaturated aliphatic hydrocarbon groups, saturated alicyclic hydrocarbon groups, unsaturated alicyclic hydrocarbon groups, or groups composed of two or more types of groups selected from among these groups. The saturated aliphatic hydrocarbon groups may be either linear or branched. The unsaturated aliphatic hydrocarbon groups may be either linear or branched.

Examples of the hydrocarbon group (X), and the total number of carbon atoms within the at least one non-aromatic hydrocarbon group contained in that hydrocarbon group (X) are presented below. Further, examples of the organic group (Y), and the total number of carbon atoms within the at least one non-aromatic hydrocarbon group contained in that organic group (Y) are also presented below as reference examples. The carbon atom within a —C(O)— group is not included in the total number of carbon atoms. Carbon atoms included in non-aromatic hydrocarbon groups in which one or more hydrogen atoms have each been substituted with a halogen atom are included in the total number of carbon atoms. In the present disclosure, the symbol “*” in a formula represents a bonding site with another atom. Groups 7 to 14 are examples of the hydrocarbon group (X), and groups 1 to 3 are examples of the organic group (Y). Groups 4 to 6 are examples of the hydrocarbon group (X) as well as examples of the organic group (Y).

TABLE 1

| | | | | Carbon |
|---|---|---|---|---|
| Group | (X)/(Y) | | Structural formula | number |
| 1 | | Organic group (Y) | 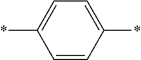 [SMILES: *c1ccc(*)cc1] | 0 |
| 2 | | | 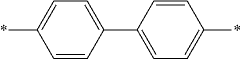 [SMILES: *c1ccc(-c2ccc(*)cc2)cc1] | 0 |
| 3 | | | 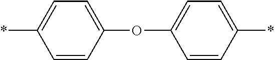 [SMILES: *c1ccc(Oc2ccc(*)cc2)cc1] | 0 |
| 4 | Organic group (X) | | 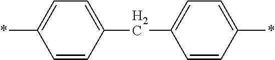 [SMILES: *c1ccc(Cc2ccc(*)cc2)cc1] | 1 |
| 5 | | | 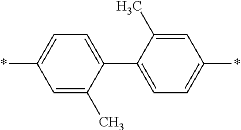 [SMILES: *c1ccc(-c2ccc(*)cc2C)c(C)c1] | 2 |
| 6 | | | 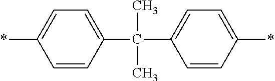 [SMILES: *c1ccc(C(C)(C)c2ccc(*)cc2)cc1] | 3 |
| 7 | | | 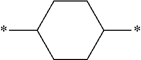 [SMILES: *C1CCC(*)CC1] | 6 |
| 8 | | | 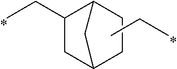 | 9 |
| 9 | | | 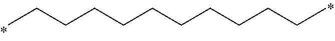 | 10 |
| 10 | | | 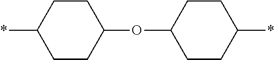 [SMILES: *C1CCC(OC2CCC(*)CC2)CC1] | 12 |
| 11 | | | 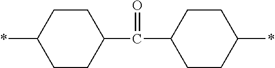 [SMILES: *C1CCC(C(=O)C2CCC(*)CC2)CC1] | 12 |
| 12 | | | 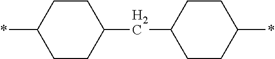 [SMILES: *C1CCC(CC2CCC(*)CC2)CC1] | 13 |
| 13 | | | 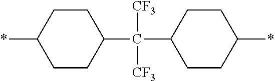 [SMILES: *C1CCC(C(C2CCC(*)CC2)(C(F)(F)F)C(F)(F)F)CC1] | 15 |
| 14 | | | 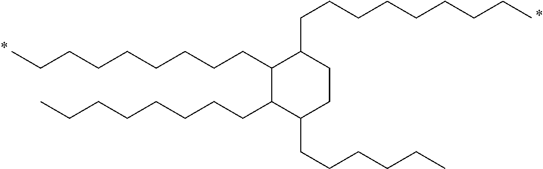 [SMILES: CCCCCCCCCC1CCC(CCCCCC)C(CCCCCCCC)C1CCCCCCCCC] | 36 |

The total number of carbon atoms within the at least one non-aromatic hydrocarbon group contained in the hydrocarbon group (X) may be within a range from 1 to 50. The number of carbon atoms is, for example, 2 or more, 3 or more, 6 or more, 9 or more, 12 or more, 16 or more, 20 or more, 24 or more, 28 or more, 32 or more, or 36 or more. The number of carbon atoms is, for example, not more than 48, not more than 44, not more than 40, or 36 or fewer. The number of carbon atoms is, for example, within a range from 6 to 50, from 9 to 50, from 12 to 48, from 20 to 44, or from 28 to 40. In those case where the block copolymer has a non-aromatic hydrocarbon group, it is thought that for reasons including an increased free volume and a reduction in polarity, a polyimide having a low dielectric constant and a low dielectric loss tangent can be obtained. In those cases where the total number of carbon atoms within the non-aromatic hydrocarbon group is 9 or more, these effects tend to be more easily obtained. In those cases where the total number of carbon atoms within the non-aromatic hydrocarbon group is not more than 50, favorable solubility in solvents tends to be better maintained.

Examples of the saturated aliphatic hydrocarbon groups, unsaturated aliphatic hydrocarbon groups, saturated alicyclic hydrocarbon groups, unsaturated alicyclic hydrocarbon groups, and groups composed of two or more of these hydrocarbon groups that may be incorporated in the hydrocarbon group (X) are listed below. The examples below may be used as the saturated aliphatic hydrocarbon group, unsaturated aliphatic hydrocarbon group, saturated alicyclic hydrocarbon group, unsaturated alicyclic hydrocarbon group, and group composed of two or more types of groups selected from among these groups mentioned in the present disclosure.

The number of carbon atoms in the saturated aliphatic hydrocarbon group is, for example, within a range from 1 to 50, from 2 to 40, from 3 to 30, from 4 to 20, or from 5 to 10. Examples of the saturated aliphatic hydrocarbon group include atom groupings in which 1 to 4 hydrogen atoms have been removed from a linear or branched alkane. Examples of the alkane include methane, ethane, propane, butane, pentane, hexane, heptane, octane, nonane, decane, undecane, dodecane, tridecane, tetradecane, pentadecane, hexadecane, heptadecane, octadecane, nonadecane, eicosane, heneicosane, docosane, tricosane, tetracosane, hexacosane, octacosane, triacontane, tetracontane, and pentacontane. In those cases where the hydrocarbon group (X) contains a saturated aliphatic hydrocarbon group having only a few carbon atoms, such as 1, 2 or 3 carbon atoms, the number of those saturated aliphatic hydrocarbon groups within the hydrocarbon group (X) may be two or more.

The number of carbon atoms in the unsaturated aliphatic hydrocarbon group is, for example, within a range from 2 to 50, from 2 to 40, from 3 to 30, from 4 to 20, or from 5 to 10. The number of carbon-carbon unsaturated bonds contained within the unsaturated aliphatic hydrocarbon group is one or more, and may be, for example, not more than 5, not more than 4, not more than 3, or 2 or fewer. The unsaturated aliphatic hydrocarbon group may be an alkene containing a single carbon-carbon double bond or an alkyne containing a single carbon-carbon triple bond. Examples of the unsaturated aliphatic hydrocarbon group include atom groupings in which 1 to 4 hydrogen atoms have been removed from a linear or branched alkene, or atom groupings in which 1 to 4 hydrogen atoms have been removed from a linear or branched alkyne. Examples of the alkene include ethene, propene, butene, pentene, hexene, heptene, octene, nonene, decene, undecene, dodecene, tridecene, tetradecene, pentadecene, hexadecene, heptadecene, octadecene, nonadecene, eicosene, heneicosene, docosene, tricosene, tetracosene, pentacosene, hexacosene, heptacosene, octacosene, nonacosene, triacontene, tetracontene, and pentacontene. Examples of the alkyne include ethyne, propyne, butyne, pentyne, hexyne, heptyne, octyne, nonyne, decyne, undecyne, dodecyne, tridecyne, tetradecyne, pentadecyne, hexadecyne, heptadecyne, octadecyne, nonadecyne, eicosyne, heneicosyne, docosyne, tricosyne, tetracosyne, pentacosyne, hexacosyne, heptacosyne, octacosyne, nonacosyne, triacontyne, tetracontyne, and pentacontyne. In those cases where the hydrocarbon group (X) contains an unsaturated aliphatic hydrocarbon group having only a few carbon atoms, such as 1, 2 or 3 carbon atoms, the number of those unsaturated aliphatic hydrocarbon groups within the hydrocarbon group (X) may be two or more.

The number of carbon atoms in the saturated alicyclic hydrocarbon group is, for example, within a range from 3 to 20, from 4 to 16, from 5 to 10, or from 6 to 8. Examples of the saturated alicyclic hydrocarbon group include atom groupings in which 1 to 4 hydrogen atoms have been removed from a cycloalkane. Examples of the cycloalkane include cyclopropane, cyclobutane, cyclopentane, cyclohexane, cycloheptane, cyclooctane, norbornane, decalin, bicyclobutane, bicyclohexane, bicyclooctane, spiropentane, spiroheptane, quadricyclane, and adamantane.

The number of carbon atoms in the unsaturated alicyclic hydrocarbon group is, for example, within a range from 4 to 20, from 5 to 10, or from 6 to 8. The number of carbon-carbon unsaturated bonds contained within the unsaturated aliphatic hydrocarbon group is one or more, and may be, for example, not more than 5, not more than 4, not more than 3, or 2 or fewer. The unsaturated aliphatic hydrocarbon may be a cycloalkene containing a single carbon-carbon double bond or a cycloalkyne containing a single carbon-carbon triple bond. Examples of the unsaturated alicyclic hydrocarbon group include atom groupings in which 1 to 4 hydrogen atoms have been removed from a cycloalkene, or atom groupings in which 1 to 4 hydrogen atoms have been removed from a cycloalkyne. Examples of the unsaturated alicyclic hydrocarbon include cyclobutene, cyclopentene, cyclopentadiene, cyclohexene, cyclohexadiene, cycloheptene, norbornene, norbornadiene, and bicyclooctadiene.

The number of carbon atoms in the “group composed of two or more types of groups selected from among these groups” is, for example, within a range from 4 to 50, from 9 to 50, from 16 to 48, from 24 to 44, or from 32 to 40. A “group composed of two or more types of groups selected from among these groups” is formed from two or more types of groups selected from the group consisting of saturated aliphatic hydrocarbon groups, unsaturated aliphatic hydrocarbon groups, saturated alicyclic hydrocarbon groups, and unsaturated alicyclic hydrocarbon groups, wherein these two or more types of groups are bonded together. Examples of the “group composed of two or more types of groups selected from among these groups” include at least one group selected from the group consisting of groups composed of a saturated aliphatic hydrocarbon group and a saturated alicyclic hydrocarbon group, groups composed of a saturated aliphatic hydrocarbon group and an unsaturated alicyclic hydrocarbon group, groups composed of an unsaturated aliphatic hydrocarbon group and a saturated alicyclic hydrocarbon group, and groups composed of an unsaturated aliphatic hydrocarbon group and an unsaturated alicyclic hydrocarbon group.

Examples of the optional group that may be incorporated in the hydrocarbon group (X) include aromatic hydrocarbon groups, aromatic heterocyclic compound groups, and groups containing a hetero atom. Examples of aromatic hydrocarbon groups, aromatic heterocyclic compound groups, and groups containing a hetero atom that may be incorporated in the hydrocarbon group (X) are listed below. The examples below may be used as the aromatic hydrocarbon group, aromatic heterocyclic compound group, and group containing a hetero atom mentioned in the present disclosure. From the viewpoint of reducing the polarity, the hydrocarbon group (X) need not contain an oxygen atom, and also need not contain a hetero atom.

The number of carbon atoms in the aromatic hydrocarbon group is, for example, within a range from 6 to 30, from 6 to 20, or from 6 to 10. Examples of the aromatic hydrocarbon group include atom groupings in which 1 to 4 hydrogen atoms have been removed from an aromatic hydrocarbon. Examples of the aromatic hydrocarbon include benzene, naphthalene, anthracene, pyrene, and perylene. The number of carbon atoms in the aromatic heterocyclic compound group is within a range from 2 to 30, from 4 to 20, or from 5 to 10. Examples of the aromatic heterocyclic compound group include atom groupings in which 1 to 4 hydrogen atoms have been removed from an aromatic heterocyclic compound. Examples of the aromatic heterocyclic compound include pyridine, furan, benzofuran, thiophene, and benzothiophene.

Examples of the group containing a hetero atom include linking groups containing a hetero atom (but excluding an imide group and amic acid group), and substituent groups containing a hetero atom. Examples of linking groups containing a hetero atom include an oxy group, thio group, sulfonyl group, sulfinyl group, carbonyl group, carbonyloxy group, and imino group. Examples of substituent groups containing a hetero atom include a hydroxy group, mercapto group, sulfo group, sulfino group, carboxy group, fluoro group, and chloro group. In the present disclosure, the carbon atom of a —C(O)— group contained in a group containing a hetero atom is not included in the total number of carbon atoms within the at least one non-aromatic hydrocarbon group.

The hydrocarbon group (X) is, for example, composed of a non-aromatic hydrocarbon group of one or more carbon atoms. In those cases where the hydrocarbon group (X) is composed of a non-aromatic hydrocarbon group of one or more carbon atoms, the hydrocarbon group (X) excludes aromatic hydrocarbon groups, aromatic heterocyclic compound groups, and groups having a hetero atom. The hydrocarbon group (X) is, for example, a saturated aliphatic hydrocarbon group; an unsaturated aliphatic hydrocarbon group; a saturated alicyclic hydrocarbon group; an unsaturated alicyclic hydrocarbon group; or a group composed of two or more types of groups selected from among saturated aliphatic hydrocarbon groups, unsaturated aliphatic hydrocarbon groups, saturated alicyclic hydrocarbon groups and unsaturated alicyclic hydrocarbon groups. The saturated aliphatic hydrocarbon group may be linear or branched. The unsaturated aliphatic hydrocarbon group may be linear or branched. In those cases where the hydrocarbon group (X) is composed of a non-aromatic hydrocarbon group, the concentration of polar groups contained in the block copolymer can be more easily reduced.

The hydrocarbon group (X) is, for example, composed of a non-aromatic hydrocarbon group of 9 or more carbon atoms. In those cases where the hydrocarbon group (X) is composed of a non-aromatic hydrocarbon group, the hydrocarbon group (X) excludes aromatic hydrocarbon groups, aromatic heterocyclic compound groups, and groups having a hetero atom. The hydrocarbon group (X) is, for example, a saturated aliphatic hydrocarbon group of 9 or more carbon atoms; an unsaturated aliphatic hydrocarbon group of 9 or more carbon atoms; a saturated alicyclic hydrocarbon group of 9 or more carbon atoms; an unsaturated alicyclic hydrocarbon group of 9 or more carbon atoms; or a group of 9 or more carbon atoms composed of two or more types of groups selected from among saturated aliphatic hydrocarbon groups, unsaturated aliphatic hydrocarbon groups, saturated alicyclic hydrocarbon groups and unsaturated alicyclic hydrocarbon groups. The saturated aliphatic hydrocarbon group may be linear or branched. The unsaturated aliphatic hydrocarbon group may be linear or branched. In those cases where the hydrocarbon group (X) is composed of a non-aromatic hydrocarbon group of 9 or more carbon atoms, the concentration of polar groups contained in the block copolymer can be more easily reduced.

The hydrocarbon group (X) preferably contains at least one type of group selected from the group consisting of saturated alicyclic hydrocarbon groups and unsaturated alicyclic hydrocarbon groups, and more preferably contains a saturated alicyclic hydrocarbon group. The number of carbon atoms in the saturated alicyclic hydrocarbon groups and unsaturated alicyclic hydrocarbon groups may be 3 or more, 5 or more, or 6 or more. The number of carbon atoms in the saturated alicyclic hydrocarbon groups and unsaturated alicyclic hydrocarbon groups may be not more than 20, not more than 10, or 8 or fewer. In those cases where the block copolymer contains at least one of a saturated alicyclic hydrocarbon group and an unsaturated alicyclic hydrocarbon group, a polyimide having a lower dielectric constant tends to be more easily obtained. It is surmised that the reason for this is that incorporating an alicyclic structure in the polyimide increases the free volume.

The hydrocarbon group (X) preferably contains at least one type of group selected from the group consisting of linear saturated aliphatic hydrocarbon groups of 6 or more carbon atoms, and linear unsaturated aliphatic hydrocarbon groups of 6 or more carbon atoms, and more preferably contains a linear saturated aliphatic hydrocarbon group of 6 or more carbon atoms. The number of carbon atoms in the linear saturated aliphatic hydrocarbon groups and linear unsaturated aliphatic hydrocarbon groups may be 8 or more, 10 or more, or 12 or more. The number of carbon atoms in the linear saturated aliphatic hydrocarbon groups and linear unsaturated aliphatic hydrocarbon groups may be not more than 30, not more than 20, or 16 or fewer. In those cases where the block copolymer contains at least one of a linear saturated aliphatic hydrocarbon group of 6 or more carbon atoms and a linear unsaturated aliphatic hydrocarbon group of 6 or more carbon atoms, a polyimide having a lower dielectric loss tangent tends to be more easily obtained. It is surmised that the reason for this is that incorporating a long-chain structure in the polyimide lowers the imide group concentration in the polyimide, namely, causes a relative reduction in the number of polar groups within the polyimide.

The hydrocarbon group (X) preferably contains at least one type of group selected from the group consisting of saturated alicyclic hydrocarbon groups and unsaturated alicyclic hydrocarbon groups, and at least one type of group selected from the group consisting of linear saturated aliphatic hydrocarbon groups of 6 or more carbon atoms, and linear unsaturated aliphatic hydrocarbon groups of 6 or more carbon atoms, and more preferably contains a saturated alicyclic hydrocarbon group and a linear saturated aliphatic hydrocarbon group of 6 or more carbon atoms.

In a number of embodiments, from the viewpoint of the balance between the dielectric constant and the dielectric loss tangent of the polyimide, the total number of carbon atoms within saturated aliphatic hydrocarbon groups and unsaturated aliphatic hydrocarbon groups contained in the hydrocarbon group (X) is greater than the total number of carbon atoms within saturated alicyclic hydrocarbon groups and unsaturated alicyclic hydrocarbon groups contained in the hydrocarbon group (X). In a number of embodiments, from the viewpoint of obtaining a low dielectric constant and a low dielectric loss tangent, the hydrocarbon group (X) contains no aromatic hydrocarbon groups or aromatic heterocyclic compound groups.

The hydrocarbon group (X) preferably contains a group represented by formula (G1) shown below.

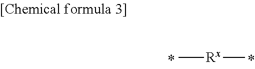

In the formula, R^{x} represents a group (X) containing at least one non-aromatic hydrocarbon group.

The hydrocarbon group (X) more preferably contains at least one type of group selected from the group consisting of groups represented by formula (G2) shown below through to groups represented by formula (G6) shown below, and groups represented by formula (GA1) shown below through to groups represented by formula (GA3b) shown below. The hydrocarbon group (X) even more preferably contains at least one type of group selected from the group consisting of groups represented by formula (G2) shown below through to groups represented by formula (G6) shown below. The hydrocarbon group (X) may contain at least one type of group selected from the group consisting of groups represented by formula (GA1) shown below through to groups represented by formula (GA3b) shown below, either instead of, or in addition to, at least one type of group selected from the group consisting of groups represented by formula (G2) shown below through to groups represented by formula (G6) shown below.

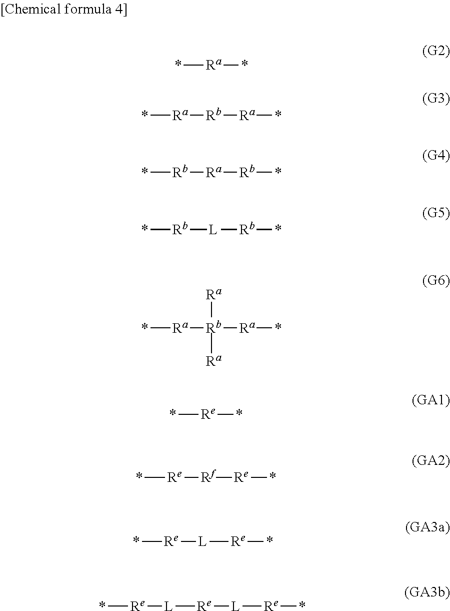

In the formulas, each R^{a} independently represents a linear or branched saturated aliphatic hydrocarbon group (having a number of carbon atoms of, for example, 1 or more, 6 or more, or 8 or more), or a linear or branched unsaturated aliphatic hydrocarbon group (having a number of carbon atoms of, for example, 1 or more, 6 or more, or 8 or more), and preferably represents a linear saturated aliphatic hydrocarbon group (having a number of carbon atoms of, for example, 1 or more, 6 or more, or 8 or more), or a linear unsaturated aliphatic hydrocarbon group (having a number of carbon atoms of, for example, 1 or more, 6 or more, or 8 or more). Each R^{b} independently represents a saturated alicyclic hydrocarbon group (having a number of carbon atoms of, for example, 4 or more, 6 or more, or 7 or more), or an unsaturated alicyclic hydrocarbon group (having a number of carbon atoms of, for example, 4 or more, 6 or more, or 7 or more), and preferably represents a saturated alicyclic hydrocarbon group (having a number of carbon atoms of, for example, 6 (a cyclohexane group) or 7 (a norbornane group)). Each R^{a} and R^{b} may, independently, have a substituent group, or have no substituent group. Examples of the substituent group include substituent groups containing a hetero atom, and in the present disclosure, examples of substituent groups containing a hetero atom include those groups exemplified above. The upper limit for the number of carbon atoms in R^{a} and R^{b} is, for example, not more than 48, not more than 44, not more than 40, or 36 or fewer.

L represents a single bond or a linking group containing a hetero atom (but excluding an imide group and amic acid group). In the present disclosure, examples of the linking group containing a hetero atom represented by L include the groups exemplified above.

Each R^{e} independently represents an aromatic hydrocarbon group or an aromatic heterocyclic compound group, preferably represents an aromatic hydrocarbon group, and more preferably represents a benzene group. Each R^{e} may, independently, have a substituent group, or have no substituent group. Examples of the substituent group that R^{e} may have include non-aromatic hydrocarbon groups and substituent groups containing a hetero atom. The non-aromatic hydrocarbon group is, for example, an alkyl group of 1 to 3 carbon atoms.

R^{f} represents a linear or branched saturated aliphatic hydrocarbon group or a linear or branched unsaturated aliphatic hydrocarbon group. The number of carbon atoms in R^{f} is, for example, within a range from 1 to 12, from 2 to 8, or from 3 to 6.

However, the groups represented by formulas (GA1) to (GA3b) contain, as either one or both of a substituent group and R^{f}, at least one non-aromatic hydrocarbon group (wherein the total number of carbon atoms is, for example, within a range from 1 to 12, from 2 to 8, or from 3 to 6). For example, in those cases where the block copolymer has a group represented by formula (GA3a) (wherein L represents a single bond, and one or both of the R^{e} groups have a non-aromatic hydrocarbon group as a substituent group), the free volume can be increased while introducing a rigid structure into the polyimide.

In a number of embodiments, in those cases where the hydrocarbon group (X) contains an aromatic cyclic group, from the viewpoint of achieving a low dielectric constant and a low dielectric loss tangent, the total number of carbon atoms in non-aromatic hydrocarbon groups may be greater than the total number of carbon atoms in the aromatic cyclic group. The total number of carbon atoms in the aromatic cyclic group is, for example, not more than 12, or 6 or fewer.

In a number of embodiments, in those cases where the hydrocarbon group (X) contains an unsaturated aliphatic hydrocarbon group with a small number of carbon atoms, such as 1, 2 or 3 carbon atoms, and an aromatic cyclic group, the number of unsaturated aliphatic hydrocarbon groups may be two or more. In such cases, the total number of carbon atoms in the non-aromatic hydrocarbon groups may be less than the total number of carbon atoms in the aromatic cyclic group.

In a number of embodiments, the hydrocarbon group (X) contains at least one type of group selected from the group consisting of groups represented by formula (G7) shown below, groups represented by formula (G8) shown below, and groups represented by formula (G9) shown below. These groups can be introduced into the block copolymer, for example, by using a dimer diamine or dimer diisocyanate as one of the monomers used for obtaining the block copolymer. The hydrocarbon group (X) preferably contains a group represented by formula (G8). In those cases where the structural unit (X) contains at least one type of group selected from the group consisting of groups represented by formula (G7), groups represented by formula (G8), and groups represented by formula (G9), satisfactory effects in lowering the dielectric constant and lowering the dielectric loss tangent tend to be more easily obtainable.

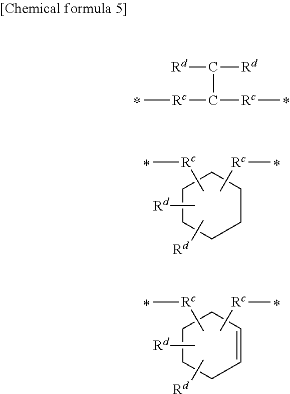

In the formulas, each R^{c} independently represents a linear alkylene group (having a number of carbon atoms of, for example, 6 or more, 8 or more, or 9 or more), or a linear alkenylene group (having a number of carbon atoms of, for example, 6 or more, 8 or more, or 9 or more), and each R^{d} independently represents a linear alkyl group (having a number of carbon atoms of, for example, 6 or more, 8 or more, or 9 or more), or a linear alkenyl group (having a number of carbon atoms of, for example, 6 or more, 8 or more, or 9 or more). Each R^{c} and R^{d} may, independently, have a substituent group, or have no substituent group. The upper limit for the number of carbon atoms in R^{c} and R^{d} is, for example, not more than 48, not more than 44, not more than 40, or 36 or fewer.

In a number of embodiments, the hydrocarbon group (X) contains at least one type of group selected from the group consisting of groups represented by formula (GA4) shown below and groups represented by formula (GA5) shown below. The hydrocarbon group (X) preferably contains a group represented by formula (GA4). In those cases where the structural unit (X) contains at least one type of group selected from the group consisting of groups represented by formula (GA4) and groups represented by formula (GA5), the effects of the invention in achieving a low dielectric constant, low dielectric loss tangent and low coefficient of thermal expansion tend to be more easily obtainable.

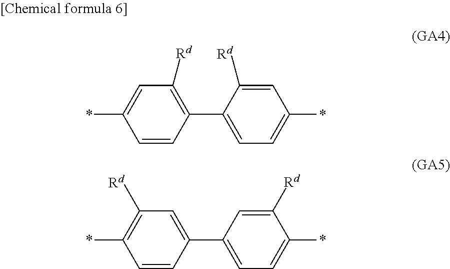

In the formulas, each R^{d} independently represents a linear alkyl group (having a number of carbon atoms of, for example, 1 or more, 2 or more, or 3 or more), or a linear alkenyl group (having a number of carbon atoms of, for example, 2 or more, 3 or more, or 4 or more). Each R^{d} may, independently, have a substituent group, or have no substituent group. The upper limit for the number of carbon atoms in R^{d} is, for example, not more than 12, not more than 8, or 6 or fewer.

### (Organic Group (Y))

The structural unit (X) may contain an organic group (Y). The organic group (Y) is a group containing at least one aromatic cyclic group. Examples of the aromatic cyclic group include aromatic hydrocarbon groups and aromatic heterocyclic compound groups. The organic group (Y) is, for example, a group containing at least one type of group selected from the group consisting of aromatic hydrocarbon groups, aromatic heterocyclic compound groups, and groups composed of two or more types of groups selected from among these groups. The organic group (Y) preferably contains an aromatic hydrocarbon group. The organic group (Y) may be an organic group containing no non-aromatic hydrocarbon group. The organic group (Y) may also contain a non-aromatic hydrocarbon group, a linking group containing a hetero atom, or a substituent containing a hetero atom or the like. The organic group (Y) is, for example, a monovalent to tetravalent group. The structural unit (X) preferably contains a divalent to tetravalent organic group (Y), more preferably contains a divalent or tetravalent organic group (Y), and even more preferably contains a tetravalent organic group (Y).

The organic group (Y) preferably contains a group represented by formula (G11) shown below.

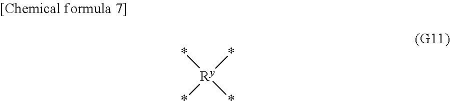

In the formula, R^{y} represents the organic group (Y).

The organic group (Y) more preferably contains at least one type of group selected from the group consisting of groups represented by formula (G12) shown below through to groups represented by formula (G14b) shown below.

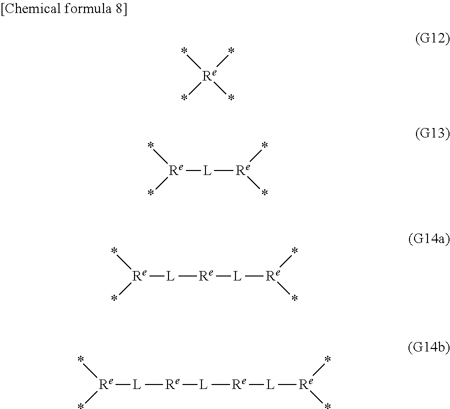

In the formulas, each R^{e} independently represents an aromatic hydrocarbon group or an aromatic heterocyclic compound group, preferably represents an aromatic hydrocarbon group, and more preferably represents a benzene group. L represents a single bond or a linking group containing a hetero atom (but excluding an imide group and amic acid group). Each R^{e} may, independently, have a substituent group, or have no substituent group.

In those cases where the block copolymer has a group represented by formula (G12), the glass transition temperature of the polyimide tends to increase. In those cases where the block copolymer has at least one type of group selected from the group consisting of groups represented by formula (G13) (wherein L is a single bond) through to groups represented by formula (G14b) (wherein L is a single bond), a rigid structure can be introduced into the polyimide. In those cases where the block copolymer has at least one type of group selected from the group consisting of groups represented by formula (G13) (wherein L is a linking group containing a hetero atom) through to groups represented by formula (G14b) (wherein L is a linking group containing a hetero atom), favorable solubility in solvents tends to be better maintained. In those cases where the block copolymer has at least one type of group selected from the group consisting of groups represented by formula (G13) (wherein L is an oxy group or a carbonyl group) through to groups represented by formula (G14b) (wherein L is an oxy group or a carbonyl group), an ether bond or carbonyl bond can be introduced into the block chain, and the dielectric constant and dielectric loss tangent tend to be more easily reduced. The block copolymer may contain a group represented by formula (G14a) (wherein L is an oxycarbonyl group), either instead of, or in addition to, at least one type of group selected from the group consisting of groups represented by formula (G13) (wherein L is an oxy group or a carbonyl group) through to groups represented by formula (G14b) (wherein L is an oxy group or a carbonyl group).

Examples of the structural unit (X) include structural units represented by formula (XI) described below and structural units represented by formula (XA) described below. In a preferred embodiment, the structural unit (X) includes at least one type of structural unit selected from the group consisting of structural units represented by formula (XI) and structural units represented by formula (XA). Examples of the structural unit (X) include the structural unit (Xd) described below. In a preferred embodiment, the structural unit (X) includes the structural unit (Xd).

### (Structural Unit (Y))

The block copolymer may contain a structural unit (Y). The structural unit (Y) is a structural unit that is different from the structural unit (X) contained in the block copolymer. The structural unit (Y) may, for example, have the organic group (Y) described above. The structural unit (Y) may also contain at least one of an imide group and an amic acid group. For example, the structural unit (Y) may be a structural unit containing the organic group (Y), and an imide group or amic acid group. The block copolymer may contain the organic group (Y) contained within the structural unit (Y), and an imide group or amic acid group within the polymer chain. The structural unit (Y) may contain one type, or two or more types, of the organic group (Y).

In the structural unit (Y), the organic group (Y) preferably contains a group represented by formula (G11) described above and a group represented by formula (G15) shown below, and more preferably contains at least one type of group selected from the group consisting of groups represented by formula (G12) described above through to groups represented by formula (G14b), and at least one type of group selected from the group consisting of groups represented by formula (G16) shown below through to groups represented by formula (G19) shown below.

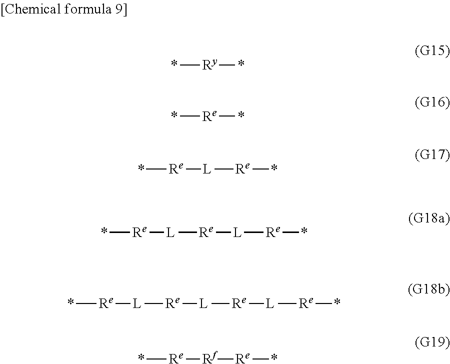

In the formulas, R^{y} represents the organic group (Y). Each R^{e} independently represents an aromatic hydrocarbon group or an aromatic heterocyclic compound group, preferably represents an aromatic hydrocarbon group, and more preferably represents a benzene group. Each R^{e} may, independently, have a substituent group, or have no substituent group. Examples of the substituent group that R^{e} may have include non-aromatic hydrocarbon groups and substituent groups containing a hetero atom. R^{f} represents a linear or branched saturated aliphatic hydrocarbon group or a linear or branched unsaturated aliphatic hydrocarbon group. The number of carbon atoms in R^{f} is, for example, within a range from 1 to 12, from 2 to 8, or from 3 to 6.

L represents a single bond or a linking group containing a hetero atom (but excluding an imide group and amic acid group).

In a number of embodiments, in those cases where the organic group (Y) contains a non-aromatic hydrocarbon group, from the viewpoint of achieving a low coefficient of thermal expansion, the total number of carbon atoms in the non-aromatic hydrocarbon group may be less than the total number of carbon atoms in the aromatic cyclic group. The total number of carbon atoms in the non-aromatic hydrocarbon group is, for example, not more than 8, not more than 6, not more than 4, or 2 or fewer.

In those cases where the block copolymer has a group represented by formula (G16), the coefficient of thermal expansion of the polyimide tends to be able to be suppressed to a low level. In those cases where the block copolymer has at least one type of group selected from the group consisting of groups represented by formula (G17) (wherein L represents a single bond) through to groups represented by formula (G18b) (wherein L represents a single bond), a rigid structure can be introduced into the polyimide, and the coefficient of thermal expansion tends to more easily reduced. In those cases where the block copolymer has at least one type of group selected from the group consisting of groups represented by formula (G17) (wherein L represents a linking group containing a hetero atom) through to groups represented by formula (G18b) (wherein L represents a linking group containing a hetero atom), favorable solubility in solvents tends to be better maintained. In those cases where the block copolymer has at least one type of group selected from the group consisting of groups represented by formula (G17) (wherein L is an oxy group or a carbonyl group) through to groups represented by formula (G18b) (wherein L is an oxy group or a carbonyl group), an ether bond or carbonyl bond can be introduced into the block chain. In those cases where the block copolymer has a group represented by formula (G17) (wherein L represents a single bond, and one or both of the R^{e} groups have a non-aromatic hydrocarbon group as a substituent group), the free volume can be increased while introducing a rigid structure into the polyimide.

Examples of the structural unit (Y) include structural units represented by formula (YI) described below and structural units represented by formula (YA) described below. In a preferred embodiment, the structural unit (Y) includes at least one type of structural unit selected from the group consisting of structural units represented by formula (YI) and structural units represented by formula (YA). One example of the structural unit (Y) is a structural unit (Yd) described below. In a preferred embodiment, the structural unit (Y) includes the structural unit (Yd).

[Block Copolymer Containing Structural Unit Represented by Formula (I) and/or Structural Unit Represented by Formula (A)]

In a number of embodiments, the block copolymer contains the polyimide block (BI) and the polyamic acid block (BA), and contains a structural unit represented by formula (I) shown below and a structural unit represented by formula (A) shown below, wherein either at least R^{A} shown below and R^{C} shown below are different, or at least R^{B} shown below and R^{D} shown below are different.

### (Structural Unit Represented by Formula (I))

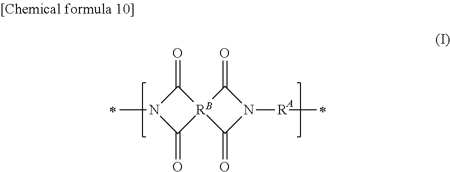

In the formula, R^{A} and R^{B} each independently represent an organic group.

### (Structural Unit Represented by Formula (A))

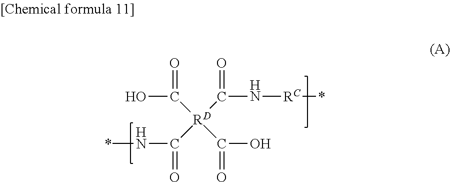

In the formula, R^{C} and R^{D} each independently represent an organic group.

Examples of the organic groups include the hydrocarbon group (X) and the organic group (Y).

Examples of the structural unit represented by formula (I) include structural units represented by formula (XI) shown below, and structural units represented by formula (YI) shown below. Examples of the structural unit represented by formula (A) include structural units represented by formula (XA) shown below, and structural units represented by formula (YA) shown below. The polyimide block (BI) contains a structural unit represented by formula (I), and the polyamic acid block (BA) contains a structural unit represented by formula (A).

In a number of embodiments, the block copolymer contains the polyimide block (BI) and the polyamic acid block (BA), and contains at least one type of structural unit selected from the group consisting of structural units represented by formula (XI) shown below and structural units represented by formula (XA) shown below. Examples of the block copolymer include block copolymers in which the polyimide block (BI) contains a structural unit represented by formula (XI); block copolymers in which the polyamic acid block (BA) contains a structural unit represented by formula (XA); and block copolymers in which the polyimide block (BI) contains a structural unit represented by formula (XI), and the polyamic acid block (BA) contains a structural unit represented by formula (XA).

The block copolymer may also contain a structural unit other than the structural unit represented by formula (XI) shown below and the structural unit represented by formula (XA) shown below. Examples of the structural unit other than the structural unit represented by formula (XI) shown below and the structural unit represented by formula (XA) shown below include structural units represented by formula (YI) shown below and structural units represented by formula (YA) shown below. The block copolymer may contain at least one type of structural unit selected from the group consisting of structural units represented by formula (YI) and structural units represented by formula (YA). The structural unit represented by formula (YI) and the structural unit represented by formula (YA) may be structural units having no hydrocarbon group (X).

The structural unit represented by formula (XI) and the structural unit represented by formula (XA) are structural units corresponding with the structural unit (X), and examples of the structural unit represented by formula (XI) and the structural unit represented by formula (XA) include the structural unit (Xd) described below. The structural unit represented by formula (YI) and the structural unit represented by formula (YA) are structural units corresponding with the structural unit (Y), and examples of the structural unit represented by formula (YI) and the structural unit represented by formula (YA) include the structural unit (Yd) described below.

### (Structural Unit Represented by Formula (XI))

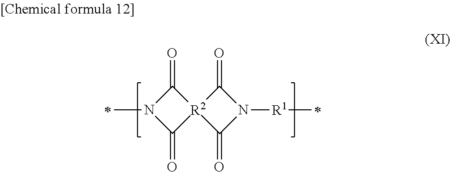

In the formula, R¹ and R² each independently represent an organic group, and at least one of R¹ and R² is the hydrocarbon group (X).

Examples of the organic group include the hydrocarbon group (X) and the organic group (Y).

In the structural unit represented by formula (XI), for example, R¹ is the hydrocarbon group (X) and R² is the organic group (Y); and it is preferable that R¹ is a group selected from the group consisting of groups represented by formula (G2) through to groups represented by formula (G6), and R² is a group selected from the group consisting of groups represented by formula (G12) through to groups represented by formula (G14b); more preferable that R¹ is a group selected from the group consisting of groups represented by formula (G4) and groups represented by formula (G7) through to groups represented by formula (G9), and R² is a group selected from the group consisting of groups represented by formula (G12) and groups represented by formula (G13); even more preferable that R¹ is a group represented by formula (G8) and R² is a group represented by formula (G13); and particularly preferable that R¹ is a group represented by formula (G8) and R² is a group represented by formula (G13) (wherein, for example, R^{e} is a benzene group and L is a carbonyl group).

### (Structural Unit Represented by Formula (XA))

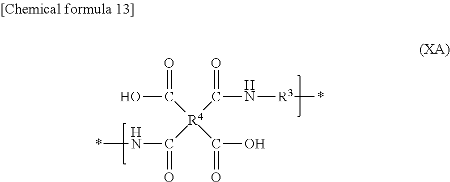

In the formula, R³ and R⁴ each independently represent an organic group, and at least one of R³ and R⁴ is the hydrocarbon group (X).

Examples of the organic group include the hydrocarbon group (X) and the organic group (Y).

In the structural unit represented by formula (XA), for example, R³ is the hydrocarbon group (X) and R⁴ is the organic group (Y); and it is preferable that R³ is a group selected from the group consisting of groups represented by formula (G2) through to groups represented by formula (G6), and R⁴ is a group selected from the group consisting of groups represented by formula (G12) through to groups represented by formula (G14b); more preferable that R³ is a group selected from the group consisting of groups represented by formula (G4) and groups represented by formula (G7) through to groups represented by formula (G9), and R⁴ is a group selected from the group consisting of groups represented by formula (G12) and groups represented by formula (G13); even more preferable that R³ is a group represented by formula (G8) and R⁴ is a group represented by formula (G13); and particularly preferable that R³ is a group represented by formula (G8) and R⁴ is a group represented by formula (G13) (wherein, for example, R^{e} is a benzene group and L is a carbonyl group).

In the structural unit represented by formula (XA), for example, R³ is the hydrocarbon group (X) and R⁴ is the organic group (Y); and it is preferable that R³ is a group selected from the group consisting of groups represented by formulas (GA1) to (GA3b), and R⁴ is a group selected from the group consisting of groups represented by formula (G12) through to groups represented by formula (G14b); more preferable that R³ is a group represented by formula (GA3a), and R⁴ is a group selected from the group consisting of groups represented by formula (G13) and groups represented by formula (G14a); even more preferable that R³ is a group selected from the group consisting of groups represented by formula (GA4) and groups represented by formula (GA5), and R⁴ is a group selected from the group consisting of groups represented by formula (G13) and groups represented by formula (G14a); and particularly preferable that R³ is a group represented by formula (GA4), and R⁴ is a group selected from the group consisting of groups represented by formula (G13) (wherein, for example, R^{e} is a benzene group and L is a single bond) and groups represented by formula (G14a) (wherein, for example, R^{e} is a benzene group and L is a carbonyl group).

### (Structural Unit Represented by Formula (YI))

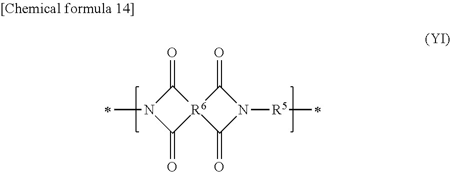

In the formula, R⁵ and R⁶ each independently represent the organic group (Y).

In the structural unit represented by formula (YI), for example, R⁵ is a group selected from the group consisting of groups represented by formula (G16) through to groups represented by formula (G19), and R⁶ is a group selected from the group consisting of groups represented by formula (G12) through to groups represented by formula (G14b); and it is preferable that R⁵ is a group represented by formula (G16), a group represented by formula (G17) or a group represented by formula (G18), and R⁶ is a group represented by formula (G12) or a group represented by formula (G13); and more preferable that R⁵ is a group represented by formula (G16) (wherein, for example, R^{e} is a benzene group), a group represented by formula (G17) (wherein, for example, R^{e} is a benzene group), or a group represented by formula (G18b) (wherein, for example, R^{e} is a benzene group and L is an oxy group), and R⁶ is a group represented by formula (G12) (wherein, for example, R^{e} is a benzene group) or a group represented by formula (G13) (wherein, for example, R^{e} is a benzene group and L is a single bond).

### (Structural Unit Represented by Formula (YA))

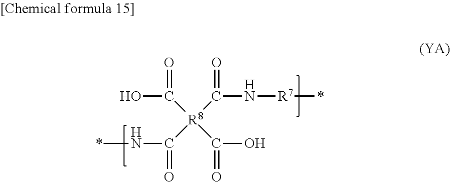

In the formula, R⁷ and R⁸ each independently represent the organic group (Y).

In the structural unit represented by formula (YA), for example, R⁷ is a group selected from the group consisting of groups represented by formula (G16) through to groups represented by formula (G19), and R⁸ is a group selected from the group consisting of groups represented by formula (G12) through to groups represented by formula (G14b); and it is preferable that R⁷ is a group represented by formula (G16), a group represented by formula (G17) or a group represented by formula (G18a), and R⁸ is a group represented by formula (G12) or a group represented by formula (G13); and more preferable that R⁷ is a group represented by formula (G16) (wherein, for example, R^{e} is a benzene group), a group represented by formula (G17) (wherein, for example, R^{e} is a benzene group), or a group represented by formula (G18b) (wherein, for example, R^{e} is a benzene group and L is an oxy group), and R⁸ is a group represented by formula (G12) (wherein, for example, R^{e} is a benzene group) or a group represented by formula (G13) (wherein, for example, R^{e} is a benzene group and L is a single bond).

### (Examples of Block Copolymer)

In a preferred embodiment, the block copolymer satisfies any one, or two or more, of the following conditions.
The block copolymer contains at least one type of structural unit selected from the group consisting of structural units represented by formula (XI) (provided that at least one of R¹ and R² is the group (X) described above, wherein the total number of carbon atoms in the at least one non-aromatic hydrocarbon group is 9 or more), and structural units represented by formula (XA) (provided that at least one of R³ and R⁴ is the group (X) described above, wherein the total number of carbon atoms in the at least one non-aromatic hydrocarbon group is 9 or more).
The block copolymer contains at least one type of structural unit selected from the group consisting of structural units represented by formula (YI) (provided that R⁵ and R⁶ each independently represent a group containing an aromatic hydrocarbon group), and structural units represented by formula (YA) (provided that R⁷ and R⁸ each independently represent a group containing an aromatic hydrocarbon group).
The block copolymer contains at least one type of structural unit selected from the group consisting of structural units represented by formula (XI) (wherein R¹ is the group (X) described above), and structural units represented by formula (XA) (wherein R³ is the group (X) described above).
The block copolymer contains at least one type of structural unit selected from the group consisting of structural units represented by formula (YI) (wherein R⁵ is a group containing an aromatic hydrocarbon group), and structural units represented by formula (YA) (wherein R⁷ is a group containing an aromatic hydrocarbon group).
The block copolymer contains a structural unit represented by formula (XI) (wherein R¹ is the group (X) described above), and a structural unit represented by formula (YA) (wherein R⁷ is a group containing an aromatic hydrocarbon group).
The block copolymer contains a structural unit represented by formula (YI) (wherein R⁵ is a group containing an aromatic hydrocarbon group), and a structural unit represented by formula (XA) (wherein R³ is the group (X) described above).
The block copolymer contains a structural unit represented by formula (XI) (wherein R¹ is the group (X) described above), and a structural unit represented by formula (XA) (wherein R³ is the group (X) described above).
The polyimide block (BI) preferably contains a structural unit represented by formula (XI), and more preferably contains a structural unit represented by formula (XI) wherein the hydrocarbon group (X) contains a saturated alicyclic hydrocarbon group.
The polyamic acid block (BA) preferably contains a structural unit represented by formula (YA), and more preferably contains a structural unit represented by formula (YA) wherein the organic group (Y) contains an aromatic hydrocarbon group.

### (Content and the Like)

In the polyimide block (BI), the amount of the hydrocarbon group (X), based on the total mass of R¹ to R⁸, is preferably within a range from 0 to 70% by mass, from 10 to 60% by mass, or from 20 to 50% by mass. In particular, in those cases where the amount of the hydrocarbon group (X) is at least 20% by mass, a polyimide having a low dielectric constant and low dielectric loss tangent can be more easily obtained. In the polyimide block (BI), the amount of the organic group (Y), based on the total mass of R¹ to R⁸, is preferably within a range from 0 to 60% by mass, from 2 to 50% by mass, or from 4 to 40% by mass. In particular, in those cases where the amount of the organic group (Y) containing an aromatic hydrocarbon group is at least 4% by mass, a polyimide having a low coefficient of thermal expansion can be more easily obtained. In the present disclosure, depending on the structures contained in the block or the polymer, the mass of one or more of R¹ to R⁸ within the “total mass of R¹ to R⁸″ may be zero.

In the polyamic acid block (BA), the amount of the hydrocarbon group (X), based on the total mass of R¹ to R⁸, is preferably within a range from 0 to 80% by mass, from 0 to 50% by mass, or from 0 to 30% by mass. In the polyamic acid block (BA), the amount of the organic group (Y), based on the total mass of R¹ to R⁸, is preferably within a range from 20 to 100% by mass, from 30 to 80% by mass, or from 40 to 60% by mass. In particular, in those cases where the amount of the organic group (Y) containing an aromatic hydrocarbon group is at least 40% by mass, a polyimide having a low coefficient of thermal expansion can be more easily obtained.

In the block copolymer, the amount of the hydrocarbon group (X), based on the total mass of R¹ to R⁸, is preferably within a range from 5 to 70% by mass, from 10 to 60% by mass, or from 20 to 50% by mass. From the viewpoint of lowering the dielectric constant and the dielectric loss tangent, the amount of the hydrocarbon group (X) is preferably large. In particular, in those cases where the amount of the hydrocarbon group (X) is at least 10% by mass, a polyimide having a low dielectric constant and low dielectric loss tangent can be more easily obtained.

In the block copolymer, the amount of the organic group (Y), based on the total mass of R¹ to R⁸, is preferably within a range from 30 to 95% by mass, from 40 to 90% by mass, or from 50 to 80% by mass. From the viewpoint of obtaining a low coefficient of thermal expansion, the organic group (Y) preferably contains an aromatic hydrocarbon group, and the amount of this type of organic group (Y) is preferably large. In particular, in those cases where the amount of the organic group (Y) containing an aromatic hydrocarbon group is at least 50% by mass, a polyimide having a low coefficient of thermal expansion can be more easily obtained.

For example, in those cases where R¹ to R⁸ include groups corresponding with only the hydrocarbon group (X) (for example, group 14 in Table 1), and groups corresponding with the hydrocarbon group (X) and the organic group (Y) (for example, group 5 in Table 1), the amount of the above hydrocarbon group (X) can be specified as the amount of “groups corresponding with only the hydrocarbon group (X)”, and the amount of the above organic group (Y) can be specified as the amount of “groups corresponding with the hydrocarbon group (X) and the organic group (Y)”. In those cases where R¹ to R⁸ include groups corresponding with the hydrocarbon group (X) and the organic group (Y) (for example, group 5 in Table 1), and groups corresponding with only the organic group (Y) (for example, group 1 in Table 1), the amount of the above hydrocarbon group (X) can be specified as the amount of “groups corresponding with the hydrocarbon group (X) and the organic group (Y)”, and the amount of the above organic group (Y) can be specified as the amount of “groups corresponding with only the organic group (Y)”. Alternatively, for example, the non-aromatic hydrocarbon groups can be differentiated on the basis of the number of carbon atoms, and the amount of the above hydrocarbon group (X) can be specified as the amount of “groups of the hydrocarbon group (X) in which the total number of carbon atoms in the non-aromatic hydrocarbon group is n or more (for example, 9 or more)), and the amount of the above organic group (Y) can be specified as the amount of “groups of the organic group (Y) in which the total number of carbon atoms in the non-aromatic hydrocarbon group is n−1 or fewer (for example, from 0 to 8)).

### (Optional Structural Units)

The block copolymer may contain one or more other optional structural units in addition to the structural unit represented by formula (I) and the structural unit represented by formula (A). In the block copolymer, the amount of these other optional structural units, for example, based on the total mass of all the structural units contained within the block copolymer, may be within a range from 0 to 10% by mass, or from 0 to 5% by mass. These other optional structural units may include structural units containing a structure derived from a trifunctional or higher polyamine or a structure derived from a trifunctional or higher polyisocyanate, structural units having an amide bond (also referred to as an amide group), structural units having an imide group and an amide group, and structural units having an amic acid group and an amide group, or the like. These optional structural units may or may not contain the hydrocarbon group (X).

[Block Copolymer Containing a Structure Derived from a Diamine or Diisocyanate and a Structure Derived from a Tetracarboxylic Dianhydride]

In a number of embodiments, the block copolymer contains the polyimide block (BI) and the polyamic acid block (BA), and has a structure derived from a diamine or diisocyanate and a structure derived from a tetracarboxylic dianhydride.

In a number of embodiments, at least one of the above structure derived from a diamine or diisocyanate and the above structure derived from a tetracarboxylic dianhydride contains a structure having the hydrocarbon group (X). Examples of structures having the hydrocarbon group (X) include structures derived from a diamine or diisocyanate that has the hydrocarbon group (X), and structures derived from a tetracarboxylic dianhydride that has the hydrocarbon group (X). In the present disclosure, the expression “diamine or diisocyanate” means “at least one type of compound selected from the group consisting of diamines and diisocyanates”.

In a number of embodiments, the above structure derived from a diamine or diisocyanate and the above structure derived from a tetracarboxylic dianhydride contain a structure having the organic group (Y). Examples of structures having the organic group (Y) include structures derived from a diamine or diisocyanate that has the organic group (Y), and structures derived from a tetracarboxylic dianhydride that has the organic group (Y).

In the present disclosure, a structural unit having a structure derived from a diamine or diisocyanate and a structure derived from a tetracarboxylic dianhydride, wherein at least one of the structure derived from the diamine or diisocyanate and the structure derived from the tetracarboxylic dianhydride has a hydrocarbon group (X) is sometimes referred to as the “structural unit (Xd)”.

(Diamine having Hydrocarbon Group (X))

The diamine having the hydrocarbon group (X) can be represented, for example, by formula (Ax) shown below.

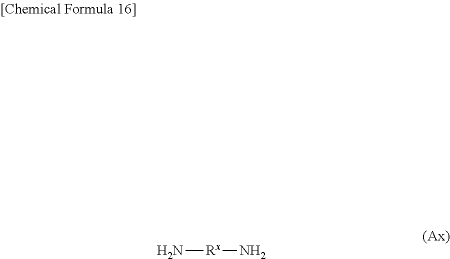

In the formula, R^{x} represents the hydrocarbon group (X). Examples of R include groups represented by the above formula (G2) through to groups represented by formula (G9), and groups represented by formula (GA1) through to groups represented by formula (GA3b).

Specific examples of the diamine having the hydrocarbon group (X) include the following:
diamines having a saturated aliphatic hydrocarbon group such as 1,2-ethylenediamine, 1,2-diaminopropane, 1,3-diaminopropane, 1,4-diaminobutane, 1,5-diaminopentane, 1,6-diaminohexane, 1,9-diaminononane, 1,10-diaminodecane, 1,11-diaminoundecane, 1,12-diaminododecane, 1,14-diaminotetradecane, and 1,16-diaminohexadecane;
diamines having an unsaturated aliphatic hydrocarbon group such as 1,9-diaminononene, 1,10-diaminodecene, 1,11-diaminoundecene, 1,12-diaminododecene, 1,14-diaminotetradecene, and 1,16-diaminohexadecene;
diamines having a saturated alicyclic hydrocarbon group such as 1,4-diaminocyclohexane, 1,3-bis(aminomethyl)cyclohexane, 1,4-bis(aminomethyl)cyclohexane, isophoronediamine, bis(aminomethyl)norbornane, 1,3-diaminoadamantane, and 4,4′-diaminodicyclohexylmethane;
diamines having an unsaturated alicyclic hydrocarbon group such as bis(aminomethyl)norbornene and 4,4′-diaminodicyclohexenylmethane;
dimer diamines such as diamines derived from dimers of unsaturated fatty acids (also referred to as dimer acids) including mono-unsaturated fatty acids such as crotonic acid, myristoleic acid, palmitoleic acid, sapienic acid, oleic acid, elaidic acid, vaccenic acid, gadoleic acid, eicosenoic acid, erucic acid, and nervonic acid; di-unsaturated fatty acids such as linoleic acid, eicosadienoic acid, and docosadienoic acid; and tri-unsaturated fatty acids such as linolenic acid, pinolenic acid, eleostearic acid, mead acid, dihomo-γ-linolenic acid, and eicosatrienoic acid; as well as diamines in which a carbon-carbon double bond within the molecule of one of the above compounds has been hydrogenated; and
diamines having a non-aromatic hydrocarbon group and an aromatic hydrocarbon group such as 4,4′-diamino-2,2′-dimethylbiphenyl (m-tolidine), 4,4′-diamino-3,3′-dimethylbiphenyl, 4,4′-diamino-3,3′-dimethyldiphenyl ether, 4,4′-diaminodiphenylmethane, 4,4′-diamino-3,3′-dimethyldiphenylmethane, 4,4′-diaminodiphenylpropane, and 2,2-bis(4-(4-aminophenoxy)phenyl)propane.

Examples of commercially available dimer diamines include the products PRIAMINE 1075 and PRIAMINE 1074 manufactured by Croda Japan Co., Ltd.

### (Diamine Having Organic Group (Y))

The diamine having the organic group (Y) can be represented, for example, by formula (Ay) shown below.

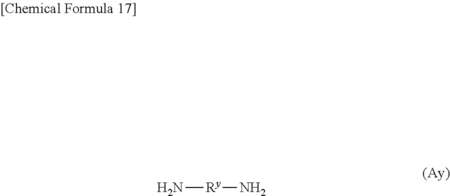

In the formula, R^{y} represents the organic group (Y). Examples of R include groups represented by the above formula (G16) through to groups represented by formula (G19).

Specific examples of the diamine having the organic group (Y) include the following:
diamines having an aromatic hydrocarbon group and having no non-aromatic hydrocarbon group, such as 1,4-phenylenediamine, 4,4′-diaminodiphenyl ether, 1,4-bis(4-aminophenoxy)benzene, and 4,4′-bis(4-aminophenoxy)biphenyl; and
the diamines exemplified above having a non-aromatic hydrocarbon group and an aromatic hydrocarbon group.

### (Diisocyanate Having Hydrocarbon Group (X))

The diisocyanate having the hydrocarbon group (X) can be represented, for example, by formula (Ix) shown below.

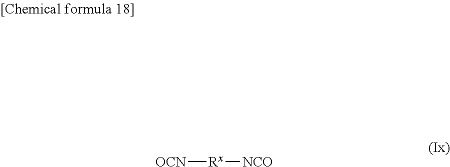

In the formula, R^{x} represents the hydrocarbon group (X). Examples of R^{x} include groups represented by the above formula (G2) through to groups represented by formula (G9), and groups represented by formula (GA1) through to groups represented by formula (GA3b).

Specific examples of the diisocyanate having the hydrocarbon group (X) include compounds having the same structures as the compounds listed above as specific examples of the above diamines but with each amino group substituted with an isocyanate group.

### (Diisocyanate Having Organic Group (Y))

The diisocyanate having the organic group (Y) can be represented, for example, by formula (Iy) shown below.

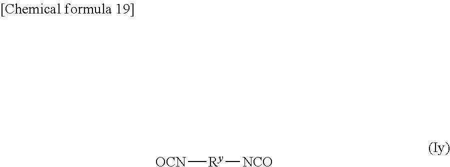

In the formula, R^{y} represents the organic group (Y). Examples of R include groups represented by the above formula (G16) through to groups represented by formula (G19).

Specific examples of the diisocyanate having the organic group (Y) include compounds having the same structures as the compounds listed above as specific examples of the above diamines but with each amino group substituted with an isocyanate group.

### (Tetracarboxylic Dianhydride Having Hydrocarbon Group (X))

The tetracarboxylic dianhydride having the hydrocarbon group (X) can be represented, for example, by formula (Cx) shown below.

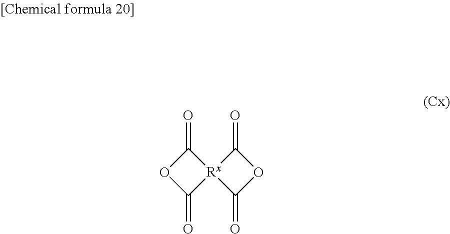

In the formula, R^{x} represents the hydrocarbon group (X). Preferred examples of the hydrocarbon group (X) are as described above.

Specific examples of the tetracarboxylic dianhydride having the hydrocarbon group (X) are listed below. In the tetracarboxylic dianhydride, when the number of carbon atoms of the hydrocarbon group (X) is counted, the carbons included in the carboxylic anhydride groups are not included in this “number of carbon atoms”.

Tetracarboxylic dianhydrides having a saturated aliphatic hydrocarbon group such as 1,2,3,4-butanetetracarboxylic dianhydride, and 1,2,5,6-hexanetetracarboxylic dianhydride;
tetracarboxylic dianhydrides having an alicyclic hydrocarbon group such as 1,2,3,4-cyclobutanetetracarboxylic dianhydride, 1,2,4,5-cyclohexanetetracarboxylic dianhydride, 3,3′,4,4′-bicyclohexyltetracarboxylic dianhydride, and 2,2-bis(3,4-dicarboxycyclohexyl)propane dianhydride; and
tetracarboxylic dianhydrides having an aromatic hydrocarbon group and a non-aromatic hydrocarbon group such as bis(2,3-dicarboxyphenyl)methane dianhydride, and bis(3,4-dicarboxyphenyl)methane dianhydride.

### (Tetracarboxylic Dianhydride Having Organic Group (Y))

The tetracarboxylic dianhydride having the organic group (Y) can be represented, for example, by formula (Cy) shown below.

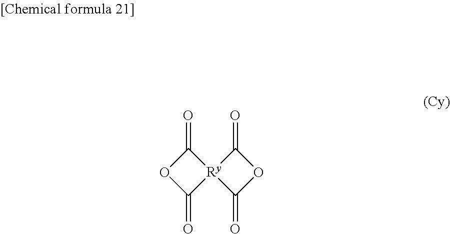

In the formula, R^{y} represents the organic group (Y). Examples of R include groups represented by the above formula (G12) through to groups represented by formula (G14b).

Specific examples of the tetracarboxylic dianhydride having the organic group (Y) include the following:
tetracarboxylic dianhydrides having an aromatic hydrocarbon group but having no non-aromatic hydrocarbon group, such as pyromellitic dianhydride, 3,3′,4,4′-biphenyltetracarboxylic dianhydride, 3,3′,4,4′-benzophenonetetracarboxylic dianhydride, 4,4′-oxydiphthalic anhydride, 3,4′-oxydiphthalic anhydride, and bis(1,3-dioxo-1,3-dihydroisobenzofuran-5-carboxylic acid)-1,4-phenylene;
tetracarboxylic dianhydrides having an aromatic heterocyclic compound group but having no non-aromatic hydrocarbon group, such as pyridinetetracarboxylic dianhydride and thiophenetetracarboxylic dianhydride; and
the tetracarboxylic dianhydrides exemplified above having an aromatic hydrocarbon group and a non-aromatic hydrocarbon group.

### (Examples of Block Copolymer)

In preferred embodiments, the block copolymer satisfies any one, or two or more, of the following conditions.
In the block copolymer, the structure derived from a diamine or diisocyanate preferably includes a structure derived from a diamine or diisocyanate having the hydrocarbon group (X); more preferably includes at least one type of structure selected from the group consisting of structures derived from a diamine or diisocyanate having a saturated aliphatic hydrocarbon group, structures derived from a diamine or diisocyanate having an unsaturated aliphatic hydrocarbon group, structures derived from a diamine or diisocyanate having a saturated alicyclic hydrocarbon group, structures derived from a diamine or diisocyanate having an unsaturated alicyclic hydrocarbon group, and structures derived from a dimer diamine or dimer diisocyanate; and even more preferably includes a structure derived from a dimer diamine or dimer diisocyanate.
In the block copolymer, the structure derived from a diamine or diisocyanate preferably includes a structure derived from a diamine or diisocyanate having the hydrocarbon group (X) in which the total number of carbon atoms within the at least one non-aromatic hydrocarbon group is 9 or more; more preferably includes at least one type of structure selected from the group consisting of structures derived from a diamine or diisocyanate of 9 or more carbon atoms having a saturated aliphatic hydrocarbon group, structures derived from a diamine or diisocyanate of 9 or more carbon atoms having an unsaturated aliphatic hydrocarbon group, structures derived from a diamine or diisocyanate of 9 or more carbon atoms having a saturated alicyclic hydrocarbon group, structures derived from a diamine or diisocyanate of 9 or more carbon atoms having an unsaturated alicyclic hydrocarbon group, and structures derived from a dimer diamine or dimer diisocyanate of 9 or more carbon atoms; and even more preferably includes a structure derived from a dimer diamine or dimer diisocyanate of 9 or more carbon atoms. The structure derived from a diamine or diisocyanate may include a structure derived from m-tolidine.
In the block copolymer, the structure derived from a diamine or diisocyanate preferably includes a structure derived from a dimer diamine or dimer diisocyanate, and a structure derived from a diamine or diisocyanate (excluding dimer diamines and dimer diisocyanates) having a saturated aliphatic hydrocarbon group; and more preferably includes a structure derived from a dimer diamine or dimer diisocyanate of 9 or more carbon atoms, and a structure derived from m-tolidine.
In the block copolymer, the structure derived from a tetracarboxylic dianhydride preferably includes a structure derived from a tetracarboxylic dianhydride having the organic group (Y); more preferably includes a structure derived from a tetracarboxylic dianhydride having an aromatic hydrocarbon group; and even more preferably includes at least one type of structure selected from the group consisting of a structure derived from pyromellitic dianhydride, a structure derived from 3,3′,4,4′-benzophenonetetracarboxylic dianhydride, and a structure derived from 3,3′,4,4′-biphenyltetracarboxylic dianhydride.
In the block copolymer, at least one of the structure derived from a diamine or diisocyanate, and the structure derived from a tetracarboxylic dianhydride includes a structure having the group (X) containing at least one non-aromatic hydrocarbon group, wherein the total number of carbon atoms in the at least one non-aromatic hydrocarbon group is 9 or more.
In the block copolymer, the structure derived from a diamine or diisocyanate, and the structure derived from a tetracarboxylic dianhydride include a structure having the organic group (Y) in which the aromatic cyclic group is an aromatic hydrocarbon group.
In the block copolymer, for example, the structure derived from a diamine or diisocyanate incorporated in the polyimide block (BI) includes a structure having the group (X) containing at least one non-aromatic hydrocarbon group.
In the block copolymer, for example, the structure derived from a diamine or diisocyanate incorporated in the polyamic acid block (BA) includes a structure derived from a diamine or diisocyanate having the organic group (Y).
In the block copolymer, for example, the structure derived from a diamine or diisocyanate incorporated in the polyimide block (BI) and the structure derived from a diamine or diisocyanate incorporated in the polyamic acid block (BA) both include a structure having the group (X) containing at least one non-aromatic hydrocarbon group.
In the block copolymer, at least the structure derived from a diamine or diisocyanate includes a structure derived from a diamine or diisocyanate having the hydrocarbon group (X), and a structure having the organic group (Y) in which the aromatic cyclic group is an aromatic hydrocarbon group.
The block copolymer contains a structure derived from a dimer diamine or dimer diisocyanate.
The block copolymer contains a structure derived from m-tolidine.
The block copolymer contains a structure derived from at least one compound selected from the group consisting of 4,4′-diaminodiphenyl ether, 1,4-bis(4-aminophenoxy)benzene, 4,4′-bis(4-aminophenoxy)biphenyl, 4,4′-diisocyanatodiphenyl ether, 1,4-bis(4-isocyanatophenoxy)benzene, and 4,4′-bis(4-isocyanatophenoxy)biphenyl.

### (Content and the Like)

In the polyimide block (BI), the amount of structures having the hydrocarbon group (X), based on the total mass of structures derived from a diamine or diisocyanate and structures derived from a tetracarboxylic dianhydride, may be, for example, within a range from 0 to 95% by mass, and is preferably from 40 to 95% by mass, from 50 to 95% by mass, or from 70 to 90% by mass. In particular, in those cases where the amount of structures having the hydrocarbon group (X) is at least 70% by mass, a polyimide having a low dielectric constant and low dielectric loss tangent can be more easily obtained. In the polyimide block (BI), the amount of structures having the organic group (Y), based on the total mass of structures derived from a diamine or diisocyanate and structures derived from a tetracarboxylic dianhydride, may be, for example, within a range from 5 to 100% by mass, and is preferably from 5 to 60% by mass, from 5 to 50% by mass, or from 10 to 30% by mass. In particular, in those cases where the amount of structures having the organic group (Y) containing an aromatic hydrocarbon group is at least 10% by mass, a polyimide having a low coefficient of thermal expansion can be more easily obtained.

In the polyamic acid block (BA), the amount of structures having the hydrocarbon group (X), based on the total mass of structures derived from a diamine or diisocyanate and structures derived from a tetracarboxylic dianhydride, is preferably within a range from 0 to 60% by mass, from 10 to 50% by mass, or from 20 to 40% by mass. In particular, in those cases where the amount of structures having the hydrocarbon group (X) is at least 10% by mass, a polyimide having a low dielectric constant and low dielectric loss tangent can be more easily obtained. In the polyamic acid block (BA), the amount of structures having the organic group (Y), based on the total mass of structures derived from a diamine or diisocyanate and structures derived from a tetracarboxylic dianhydride, is preferably within a range from 30 to 100% by mass, from 50 to 95% by mass, or from 70 to 90% by mass. In particular, in those cases where the amount of structures having the organic group (Y) containing an aromatic hydrocarbon group is at least 70% by mass, a polyimide having a low coefficient of thermal expansion can be more easily obtained.

In the block copolymer, the amount of structures having the hydrocarbon group (X), based on the total mass of structures derived from a diamine or diisocyanate and structures derived from a tetracarboxylic dianhydride, is preferably within a range from 3 to 60% by mass, from 5 to 50% by mass, or from 10 to 40% by mass. From the viewpoint of lowering the dielectric constant and the dielectric loss tangent, the amount of structures having the hydrocarbon group (X) is preferably large. In particular, in those cases where the amount of structures having the hydrocarbon group (X) is at least 5% by mass, a polyimide having a low dielectric constant and low dielectric loss tangent can be more easily obtained.

In the block copolymer, the amount of structures having the organic group (Y), based on the total mass of structures derived from a diamine or diisocyanate and structures derived from a tetracarboxylic dianhydride, is preferably within a range from 40 to 97% by mass, from 50 to 95% by mass, or from 60 to 90% by mass. From the viewpoint of obtaining a low coefficient of thermal expansion, the organic group (Y) preferably contains an aromatic hydrocarbon group, and the amount of structures having this type of organic group (Y) is preferably large. In particular, in those cases where the amount of structures having the organic group (Y) containing an aromatic hydrocarbon group is at least 50% by mass, a polyimide having a low coefficient of thermal expansion can be more easily obtained.

In terms of the above amount of structures having the hydrocarbon group (X) and amount of structures having the organic group (Y), in a similar manner to that described above for R¹ to R⁸, the amounts may be classified into “groups corresponding with only the hydrocarbon group (X)”, “groups corresponding with the hydrocarbon group (X) and the organic group (Y)” or “groups corresponding with only the organic group (Y)” or the like, or alternatively, may be classified based on the number of carbon atoms in the non-aromatic hydrocarbon group, and then applied to the block copolymer.

### (Optional Structures)

The block copolymer may also contain other optional structures besides the structure derived from a diamine or diisocyanate and the structure derived from a tetracarboxylic dianhydride. In the block copolymer, the amount of these other optional structural units, for example, based on the total mass of all the structures contained within the block copolymer, is within a range from 0 to 10% by mass, or from 0 to 5% by mass. These other optional structures may include structures derived from a trifunctional or higher polyamine or polyisocyanate, structures derived from a dicarboxylic acid compound, and structures derived from a tricarboxylic acid compound. These optional structural units may or may not contain the hydrocarbon group (X).

### [Block Copolymer Obtained Using Diamine or Diisocyanate and Tetracarboxylic Dianhydride]

In a number of embodiments, the block copolymer is a block copolymer obtained using a polyimide (PI) obtained using a diamine or diisocyanate and a tetracarboxylic dianhydride, and a polyamic acid (PA) obtained using a diamine and a tetracarboxylic dianhydride. In a number of embodiments, at least one component selected from the group consisting of the diamine or diisocyanate and the tetracarboxylic dianhydride used in obtaining the polyimide (PI), and the diamine and the tetracarboxylic dianhydride used in obtaining the polyamic acid (PA) may have the hydrocarbon group (X). Methods for obtaining the polyimide (PI), the polyamic acid (PA) and the block copolymer are described below.

### [Polyimide Block (BI)]

By including the polyimide block (BI) in the block copolymer, the occurrence of exchange reactions or the formation of crosslinking when obtaining the block copolymer or during ring closing of the amic acid groups can be prevented.

In the present disclosure, in the polyimide block (BI), the amount of imide groups relative to the total of all the imide groups and amic acid groups is, for example, greater than 50 mol %, 80 mol % or more, or 90 mol % or more. The upper limit for the amount of imide groups may be 100 mol %. In the present disclosure, these amounts can be measured by Fourier transform infrared spectroscopy (FTIR).

The polyimide block (BI) may or may not contain the structural unit (X). For example, in the block copolymer, in those cases where the polyimide block (BI) does not contain the structural unit (X), the polyimide block (BI) contains the structural unit (Y). For example, in the block copolymer, in those cases where the polyimide block (BI) does not contain the structural unit (X), the polyamic acid block (BA) contains the structural unit (X).

The number average molecular weight of the polyimide block (BI) is, for example, at least 500, at least 1,000, at least 2,000, or 3,000 or greater. The number average molecular weight of the polyimide block (BI) is, for example, not more than 10,000, not more than 8,000, not more than 7,000, or 5,000 or less. Provided the number average molecular weight is at least 500, a polyimide having a small coefficient of thermal expansion tends to be more easily obtained. Provided the number average molecular weight is not more than 10,000, favorable solubility of the block copolymer in solvents tends to be better ensured. The number average molecular weight of the polyimide block (BI) is, for example, within a range from 500 to 10,000, from 1,000 to 8,000, from 2,000 to 7,000, or from 3,000 to 5,000. In the present disclosure, number average molecular weights can be measured by gel permeation chromatography (GPC) using a calibration curve of standard polystyrenes. Specifically, measurement may be conducted using the method described in the examples.

The polyimide block (BI) may be a linear polymer block or a branched polymer block, but is preferably a linear polymer block.

### [Polyamic Acid Block (BA)]

By including the polyamic acid block in the block copolymer, favorable solubility in solvents tends to be more easily achieved.

In the present disclosure, in the polyamic acid block (BA), the amount of amic acid groups relative to the total of all the imide groups and amic acid groups is, for example, greater than 50 mol %, 80 mol % or more, or 90 mol % or more. The upper limit for the amount of amic acid groups may be 100 mol %. These amounts can be measured by FTIR.

The polyamic acid block (BA) may or may not contain the structural unit (X). For example, in the block copolymer, in those cases where the polyamic acid block (BA) does not contain the structural unit (X), the polyamic acid block (BA) contains the structural unit (Y). For example, in the block copolymer, in those cases where the polyamic acid block (BA) does not contain the structural unit (X), the polyimide block (BI) contains the structural unit (X).

The number average molecular weight of the polyamic acid block (BA) is, for example, at least 500, at least 1,000, at least 3,000, or 4,000 or greater. The number average molecular weight of the polyamic acid block (BA) is, for example, not more than 30,000, not more than 25,000, not more than 20,000, or 10,000 or less. Provided the number average molecular weight is at least 500, favorable film formability tends to be more easily obtained. Provided the number average molecular weight is not more than 30,000, a composition containing the block copolymer and a solvent tends to be more easily prepared with a viscosity suitable for coating. The number average molecular weight of the polyamic acid block (BA) is, for example, within a range from 500 to 30,000, from 1,000 to 25,000, from 3,000 to 20,000, or from 4,000 to 10,000.

The polyamic acid block (BA) may be a linear polymer block or a branched polymer block, but is preferably a linear polymer block.

### [Molecular Weight of Block Copolymer, Amount of Structural Unit (X) and the Like]

By including the polyimide block (BI) and the polyamic acid block (BA) in the block copolymer, a polyimide having a combination of a low dielectric constant and low dielectric loss tangent, and a low coefficient of thermal expansion can be more easily obtained. It is thought that this is because having a block structure allows the polyimide molecules to align more readily.

In the block copolymer, either only one of the polyimide block (BI) and the polyamic acid block (BA) contains the hydrocarbon group (X), or both the polyimide block (BI) and the polyamic acid block (BA) contain the hydrocarbon group (X). The polyimide block (BI) and the polyamic acid block (BA) may each, independently, contain either one type, or two or more types, of the hydrocarbon group (X). In the block copolymer, either only one of the polyimide block (BI) and the polyamic acid block (BA) contains the organic group (Y), or both the polyimide block (BI) and the polyamic acid block (BA) contain the organic group (Y). The polyimide block (BI) and the polyamic acid block (BA) may each, independently, contain either one type, or two or more types, of the organic group (Y).

In the block copolymer, the organic group (Y) is a group that is different from the hydrocarbon group (X) contained in the block copolymer. Using the groups in Table 1 as examples, a block copolymer having one group selected from among groups 7 to 14, and one group selected from among groups 1 to 3 is a block copolymer having both the hydrocarbon group (X) and the organic group (Y). A block copolymer having one group selected from among groups 7 to 14, and one group selected from among groups 4 to 6 is a block copolymer having both the hydrocarbon group (X) and the organic group (Y). A block copolymer having one group selected from among groups 4 to 6, and one group selected from among groups 1 to 3 is a block copolymer having both the hydrocarbon group (X) and the organic group (Y). A block copolymer having the group 6 and the group 4 is a block copolymer having both the hydrocarbon group (X) and the organic group (Y).

The number average molecular weight of the block copolymer is, for example, at least 5,000, at least 10,000, at least 20,000, or 30,000 or greater. The number average molecular weight of the block copolymer is, for example, not more than 100,000, not more than 80,000, not more than 70,000, or 60,000 or less. Provided the number average molecular weight is at least 5,000, favorable film formability tends to be more easily obtained. Provided the number average molecular weight is not more than 100,000, a composition containing the block copolymer and a solvent tends to be more easily prepared with a viscosity suitable for coating. The number average molecular weight of the block copolymer is, for example, within a range from 5,000 to 100,000, from 10,000 to 80,000, from 20,000 to 70,000, or from 30,000 to 60,000.

The amount of the polyimide block (BI) in the block copolymer, based on the total mass of the block copolymer, is greater than 0% by mass but less than 100% by mass. The amount of the polyimide block (BI) is, for example, greater than 0% by mass, at least 30% by mass, at least 60% by mass, or 90% by mass or greater. The amount of the polyimide block (BI) is, for example, less than 100% by mass, not more than 70% by mass, not more than 40% by mass, or 10% by mass or less. The amount of the polyimide block (BI) is, for example, greater than 0% by mass but not more than 70% by mass, greater than 0% by mass but not more than 40% by mass, at least 30% by mass but less than 100% by mass, or at least 60% by mass but less than 100% by mass. The amount of the polyimide block (BI) may be, for example, within a range from 30 to 70% by mass, or from 35 to 65% by mass.

The amount of the polyamic acid block (BA) in the block copolymer, based on the mass of the block copolymer, is greater than 0% by mass but less than 100% by mass. The amount of the polyamic acid block (BA) is, for example, greater than 0% by mass, at least 30% by mass, at least 60% by mass, or 90% by mass or greater. The amount of the polyamic acid block (BA) is, for example, less than 100% by mass, not more than 70% by mass, not more than 40% by mass, or 10% by mass or less. The amount of the polyamic acid block (BA) is, for example, greater than 0% by mass but not more than 70% by mass, greater than 0% by mass but not more than 40% by mass, at least 30% by mass but less than 100% by mass, or at least 60% by mass but less than 100% by mass. The amount of the polyamic acid block (BA) may be, for example, within a range from 30 to 70% by mass, or from 35 to 65% by mass.

A larger amount of the polyimide block (BI) enables the occurrence of exchange reactions or the formation of crosslinking when obtaining the block copolymer or during ring closing of the amic acid groups to be better prevented. On the other hand, a larger amount of the polyamic acid block (BA) improves the solubility of the block copolymer in organic solvents.

In the block copolymer, for example, the number average molecular weight of the polyimide block (BI) is smaller than the number average molecular weight of the polyamic acid block (BA). The block copolymer preferably contains a polyimide block (BI) and a polyamic acid block (BA) having a larger number average molecular weight than the polyimide block (BI). In those cases where the number average molecular weight of the polyimide block (BI) is smaller than the number average molecular weight of the polyamic acid block (BA), the block copolymer can be synthesized more easily, and the solubility of the block copolymer tends to be better ensured. By including a polyamic acid block (BA) having a larger number average molecular weight than that of the polyimide block (BI), a block copolymer having a satisfactory number average molecular weight tends to be more easily synthesized.

The block copolymer is preferably a copolymer for which a polyimide film obtained using the block copolymer satisfies at least one of the relative dielectric constant, the dielectric loss tangent and the coefficient of thermal expansion described below. It is particularly preferable that the block copolymer is a copolymer for which the polyimide film obtained using the block copolymer either satisfies the relative dielectric constant and the dielectric loss tangent described below, or satisfies the relative dielectric constant, the dielectric loss tangent and the coefficient of thermal expansion described below.

### [Optional Components]

In a number of embodiments, the antenna substrate material may also contain other optional components such as thermoplastic resins, organic fillers, flame retardants, flame retardancy assistants, ultraviolet absorbers, peroxides, antioxidants, photopolymerization initiators, fluorescent whiteners, and adhesion improvers.

### [Characteristics, Uses and the Like]

In a number of embodiments, the antenna substrate material may be used to obtain a polyimide material having a low dielectric constant, a low dielectric loss tangent, and a low coefficient of thermal expansion. The polyimide film obtained using the antenna substrate material preferably satisfies at least one of the relative dielectric constant, the dielectric loss tangent, and the coefficient of thermal expansion described below. It is particularly preferable that the polyimide film obtained using the antenna substrate material satisfies the relative dielectric constant and the dielectric loss tangent described below, or satisfies the relative dielectric constant, the dielectric loss tangent and the coefficient of thermal expansion described below.

### <Method for Manufacturing Antenna Substrate Material>

In a number of embodiments, the method for manufacturing the antenna substrate material containing the block copolymer includes: obtaining a polyimide (PI) using a diamine or diisocyanate and a tetracarboxylic dianhydride, obtaining a polyamic acid (PA) using a diamine and a tetracarboxylic dianhydride, and obtaining a block copolymer using the polyimide (PI) and the polyamic acid (PA). In a number of embodiments, at least one compound selected from the group consisting of the diamine or diisocyanate and the tetracarboxylic dianhydride used in obtaining the polyimide (PI), and the diamine and the tetracarboxylic dianhydride used in obtaining the polyamic acid (PA) may have the hydrocarbon group (X). By using this manufacturing method, an antenna substrate material of an embodiment described above can be manufactured with ease.

Synthesis of the polyimide (PI) and the polyamic acid (PA) may be conducted using monomers such as the diamines, diisocyanates, tetracarboxylic dianhydrides, polyamines, polyisocyanates, dicarboxylic acid compounds and tricarboxylic acid compounds described above.

Reaction of the monomers may be conducted by solution polymerization. Examples of solvents that may be used during the reaction include polar solvents such as N-methyl-2-pyrrolidone (NMP), N-ethyl-2-pyrrolidone (NEP), 7-butyrolactone (GBL), N,N′-dimethylacetamide, 3-methoxy-N,N-dimethylpropanamide (MPA), N,N′-dimethylformamide, N,N′-dimethylpropyleneurea [1,3-dimethyl-3,4,5,6-tetrahydropyridimin-2(1H)-one], dimethyl sulfoxide, diethylene glycol dimethyl ether, triethylene glycol dimethyl ether, and sulfolane; aromatic hydrocarbon solvents such as cyclohexanone, xylene, and toluene; and ketone-based solvents such as methyl ethyl ketone and methyl isobutyl ketone. The solvent preferably includes at least one type of solvent selected from the group consisting of N-methyl-2-pyrrolidone (NMP), N-ethyl-2-pyrrolidone (NEP), 7-butyrolactone (GBL), and 3-methoxy-N,N-dimethylpropanamide (MPA), and more preferably includes at least one type of solvent selected from the group consisting of N-methyl-2-pyrrolidone (NMP), 7-butyrolactone (GBL), and 3-methoxy-N,N-dimethylpropanamide (MPA).

The amount used of the solvent, per 100 parts by mass of the total mass of monomers, is preferably within a range from 100 to 600 parts by mass, and more preferably from 200 to 500 parts by mass. By ensuring that the amount used of the solvent is at least 100 parts by mass, each of the monomers can be reacted in a uniform manner. By ensuring that the amount used of the solvent is not more than 600 parts by mass, the polymerization reaction can be accelerated. Further, by ensuring that the amount used of the solvent is not large, a polyimide (PI)-containing solution or polyamic acid (PA)-containing solution containing the polyimide (PI) or polyamic acid (PA) in a high concentration can be obtained.

There are no particular limitations on the reaction temperature during synthesis of the polyamic acid using the monomers. The reaction temperature may be, for example, within a range from 10 to 50° C., or from 20 to 40° C. The reaction time is, for example, within a range from 30 minutes to 24 hours, from 1 to 12 hours, or from 3 to 6 hours. The reaction time may be regulated by sampling the reaction product, measuring the number average molecular weight, or the concentration of residual amino groups or isocyanate groups or the like, and then adjusting the reaction time so as to obtain the intended reaction product.

There are no particular limitations on the temperature when obtaining a polyimide from the polyamic acid (namely, during the imidization). The imidization temperature may be, for example, within a range from 120 to 200° C., or from 160 to 180° C. The reaction time is, for example, within a range from 30 minutes to 24 hours, from 1 to 12 hours, or from 3 to 6 hours. The reaction time may be regulated by sampling the reaction product, measuring the number average molecular weight, or the concentration of residual amic acid groups or the like, and then adjusting the reaction time so as to obtain the intended reaction product.

In order to facilitate synthesis, it is preferable that the terminals of the polymer chain of the polyimide (PI) are carboxylic anhydride groups, and the terminals of the polymer chain of the polyamic acid (PA) are amino groups. The ratio between the diamine or diisocyanate and the tetracarboxylic dianhydride used in obtaining the polyimide (PI) is equivalent to, for example, greater than 1.00 mol %, at least 1.05 mol %, or at least 1.10 mol % of the tetracarboxylic dianhydride, based on the amount of the diamine or diisocyanate. The ratio between the diamine and the tetracarboxylic dianhydride used in obtaining the polyamic acid (PA) is equivalent to, for example, less than 1.00 mol %, not more than 0.98 mol %, or 0.97 mol % or less of the tetracarboxylic dianhydride, based on the amount of the diamine.

The block copolymer is synthesized using the polyimide (PI) and the polyamic acid (PA). In the synthesis, another optional polymer may also be used.

The reaction of the polyimide (PI) and the polyamic acid (PA) may be conducted by solution polymerization. The solvents mentioned above may be used as the solvent during reaction.

There are no particular limitations on the reaction temperature. From the viewpoint of ensuring satisfactory progress of the reaction, the reaction temperature may be, for example, within a range from 20 to 100° C., from 30 to 80° C., or from 40 to 70° C. The reaction time is, for example, within a range from 30 minutes to 24 hours, from 1 to 12 hours, or from 3 to 6 hours. The reaction time may be regulated by sampling the reaction product, measuring the number average molecular weight, or the concentration of residual amino groups or isocyanate groups or the like, and then adjusting the reaction time so as to obtain the intended reaction product.

### <Antenna Substrate Material Composition>

In a number of embodiments, the antenna substrate material composition contains the antenna substrate material of one of the embodiments described above and a solvent. Examples of the solvent contained in the composition include the reaction solvents described above that can be used during synthesis of the block copolymer. The solvent is preferably at least one type of solvent selected from the group consisting of N-methyl-2-pyrrolidone (NMP), N-ethyl-2-pyrrolidone (NEP), 7-butyrolactone (GBL), and 3-methoxy-N,N-dimethylpropanamide (MPA), and is more preferably at least one type of solvent selected from the group consisting of N-ethyl-2-pyrrolidone (NEP), 7-butyrolactone (GBL), and 3-methoxy-N,N-dimethylpropanamide (MPA).

The composition may also contain optional components such as polyamides, polyethersulfones, acrylic polymers, epoxy compounds, isocyanate compounds, melamine compounds, fillers, antifoaming agents, preservatives, and surfactants. The composition can be manufactured, for example, using a method in which the block copolymer and the solvent are mixed and stirred, together with any optional components that may be used as necessary. The composition may be, for example, a composition containing no photoacid generator, a composition containing no crosslinking agent, a composition containing no photosensitizer, or a composition containing no photopolymerization initiator or the like. The composition may be a thermosetting composition or a photosensitive composition. From the viewpoints of having superior storage stability, and enabling formation of a polyimide material in the form of a film, layer, or membrane or the like using a simple method, the composition is preferably a composition that does not have photosensitivity. In a number of embodiments, the composition may be a composition that excludes cases in which the composition contains at least one component selected from the group consisting of photoacid generators, crosslinking agents, photosensitizers, and photopolymerization initiators.

The amount of the block copolymer may be set to an amount appropriate for the intended application for the composition. The amount of the block copolymer, based on the mass of the composition, is, for example, within a range from 5 to 50% by mass, from 8 to 40% by mass, or from 10 to 30% by mass.

### <Polyimide Material>

In a number of embodiments, a polyimide material can be obtained using the antenna substrate material of one of the embodiments described above, or the composition of one of the embodiments described above. For example, because the block copolymer contains the polyamic acid block (BA), the polyimide can be obtained by a ring-closing of the amic acid groups to achieve a conversion to imide groups (in the present disclosure, this conversion is sometimes referred to as an “imidization”). There are no particular limitations on the imidization method. In terms of simplicity, a method in which the block copolymer is heated can be used favorably. The heating temperature is, for example, within a range from 250 to 400° C. The polyimide material contains a polyimide, and may also contain other optional components. These optional components may be, for example, the above optional components that may be included in the antenna substrate material or the composition.

The polyimide obtained from the block copolymer contains the polyimide block (BI), and a polyimide block (BI-A) that represents the imidized block of the polyamic acid block (BA). The polyimide block (BI) and the polyimide block (BI-A) are different blocks. As a result of having a block structure, the polyimide exhibits a low coefficient of thermal expansion. In those cases where the polyimide has the hydrocarbon group (X), the polyimide tends to exhibit a low dielectric constant and a low dielectric loss tangent. Moreover, when the polyimide has the hydrocarbon group (X), the polyimide tends to exhibit low coefficient of water absorption.

From the viewpoint, for example, of achieving superior insulation properties across a broad frequency band, the relative dielectric constant of the polyimide material in a frequency range from 10 to 100 GHz, or a frequency range from 10 to 300 GHz, is not more than 3.50, not more than 3.00, not more than 2.95, not more than 2.90, not more than 2.85, or 2.80 or less. The relative dielectric constant of the polyimide material is not particularly limited, but for example, is typically at least 2.0. The relative dielectric constant (Dk) of the polyimide material can be measured by the balanced circular disk resonance method under conditions including a measurement temperature of 25° C., by using a film (for example, with a thickness of 100 μm) formed using the antenna substrate material or composition. The relative dielectric constant (Dk) may be the value determined by thoroughly drying the polyimide film, subsequently leaving the film to stand in an atmosphere at a temperature of 23° C. and a relative humidity of 50% for 24 hours, and then conducting measurement of the value immediately thereafter. The relative dielectric constant of the polyimide material preferably satisfies the above range at a frequency of 10 GHz, more preferably satisfies the above range at frequencies of 10 GHz and 100 GHz, even more preferably satisfies the above range at frequencies of 10 GHz, 30 GHz, 50 GHz and 100 GHz, and particularly preferably satisfies the above range at frequencies of 10 GHz, 30 GHz, 50 GHz, 100 GHz and 300 GHz.

From the viewpoint, for example, of suppressing transmission loss across a broad frequency band, the dielectric loss tangent of the polyimide material in a frequency range from 10 to 100 GHz, or a frequency range from 10 to 300 GHz, is not more than 0.0100, not more than 0.0070, not more than 0.0050, not more than 0.0040, not more than 0.0030, or 0.0020 or less. The dielectric loss tangent of the polyimide material is not particularly limited, but for example, is typically at least 0.0005. The dielectric loss tangent (Df) can be measured using a polyimide film (for example, with a thickness of 100 μm) by the balanced circular disk resonance method under conditions including a measurement temperature of 25° C. The dielectric loss tangent (Df) may be the value determined by thoroughly drying the polyimide film, subsequently leaving the film to stand in an atmosphere at a temperature of 23° C. and a relative humidity of 50% for 24 hours, and then conducting measurement of the value immediately thereafter. The dielectric loss tangent of the polyimide material preferably satisfies the above range at a frequency of 10 GHz, more preferably satisfies the above range at frequencies of 10 GHz and 100 GHz, even more preferably satisfies the above range at frequencies of 10 GHz, 30 GHz, 50 GHz and 100 GHz, and particularly preferably satisfies the above range at frequencies of 10 GHz, 30 GHz, 50 GHz, 100 GHz and 300 GHz.

From the viewpoint, for example, of achieving superior heat resistance, the coefficient of thermal expansion (CTE) of the polyimide material is not more than 80 ppm/K, not more than 50 ppm/K, or 20 ppm/K or less. In consideration of the fact that the polyimide film is used, for example, by bonding to another material, the coefficient of thermal expansion of the polyimide material is at least −5 ppm/K, at least 0 ppm/K, at least 10 ppm/K, or 15 ppm/K or greater. The coefficient of thermal expansion (ppm/K) can be determined using a polyimide film (for example, with a thickness of 25 μm), and is calculated as the mean coefficient of linear thermal expansion (ppm/° C.) across a temperature range from 30 to 200° C. measured using a thermomechanical analyzer under conditions including a rate of temperature increase of 10° C./minute.

From the viewpoint, for example, of the heat resistance, the glass transition temperature (Tg) of the polyimide material is at least 200° C., at least 250° C., or 300° C. or higher. The glass transition temperature (Tg) of the polyimide material is not particularly limited, but for example, is typically not more than 600° C. The glass transition temperature can be determined using a polyimide film (for example, with a thickness of 25 μm), and is calculated as the temperature (° C.) corresponding with the inflection point of a coefficient of linear thermal expansion curve across a temperature range from 30 to 200° C. measured using a thermomechanical analyzer under conditions including a rate of temperature increase of 10° C./minute.

More specifically, the relative dielectric constant, dielectric loss tangent, coefficient of thermal expansion and glass transition temperature of the polyimide material may each be measured by producing a polyimide film in accordance with the method disclosed in the examples, and then conducting measurements using the produced polyimide film in accordance with the respective method disclosed in the examples.

### <Metal-Clad Laminate>

In a number of embodiments, a metal-clad laminate can be obtained using the antenna substrate material or the composition according to one of the embodiments described above. A metal-clad laminate is used for obtaining an antenna substrate. The metal-clad laminate may be a flexible substrate or a rigid substrate. The metal-clad laminate has a polyimide material layer and a metal layer that contacts the polyimide material layer. The antenna substrate may have a metal layer on only one surface of the polyimide material layer, or may have metal layers on both surfaces of the polyimide material layer. The polyimide material layer may be a single polyimide material layer, or may include a plurality of polyimide material layers. In those cases where the insulating substrate contains a plurality of polyimide material layers, the insulating substrate may have an adhesive layer between adjacent polyimide layers.

The material of the metal layer may be, for example, copper, aluminum, gold, silver, or an alloy of these metals. The metal layer is preferably a copper foil. The polyimide layer exhibits superior adhesion to copper foils having low surface roughness such as unroughened copper foils and low-roughness copper foils. By using a copper foil with low surface roughness, transmission loss can be suppressed. For example, the copper foil may have a surface roughness according to JIS B 0601:2001 (ten-point mean roughness: Rz_{JIS}) of not more than 3.0 μm, not more than 2.0 μm, or 1.0 μm or less. The lower limit for the surface roughness is not particularly limited, but for example, is typically at least 0.5 μm. Examples of the metal-clad laminate include flexible copper-clad laminates (FCCL) and the like.

### <Antenna Substrate>

In a number of embodiments, an antenna substrate is obtained using the antenna substrate material, the composition, or the metal-clad laminate according to one of the embodiments described above. The antenna substrate may be a printed board. Examples of printed boards include flexible boards and rigid boards. Examples of printed boards include single-sided boards, double-sided boards, and multilayer boards. For example, organic materials incorporated in the printed board, such as the insulating substrate material, protective film and insulating layer may be obtained using the above antenna substrate material or composition. The organic materials incorporated in the printed board, such as the insulating substrate material, protective film and insulating layer may contain the polyimide material of an embodiment described above.

In the antenna substrate, because the polyimide material exhibits little variation in dielectric characteristics across a wide frequency band (for example, from millimeter waves to terahertz waves), the antenna substrate can be used with all manner of frequency bands. Further, the antenna substrate can also be used as a substrate for an antenna that operates in a plurality of frequency bands. In the antenna substrate, because the polyimide material exhibits favorable adhesion to the conductive layer, design freedom is broad, handling is simple, and the antenna substrate can be manufactured with good efficiency. In the antenna substrate, because the polyimide material has a low coefficient of thermal expansion and excellent dimensional stability, an antenna with favorable antenna gain can be obtained, and the antenna can also be used across a plurality of frequency bands.

In a number of embodiments, the antenna substrate has an insulating substrate, and a conductive layer that contacts the insulating substrate. The antenna substrate may have a conductive layer on only one surface of the insulating substrate, or may have conductive layers on both surfaces of the insulating substrate. The insulating substrate may contain a single polyimide material layer or a plurality of polyimide material layers. The insulating substrate may have an insulating layer other than a polyimide material layer. The insulating layer may be, for example, an insulating film, an insulating sheet, or a prepreg or the like. In those cases where the insulating substrate contains a plurality of layers selected from among polyimide material layers and insulating layers other than polyimide material layers, the insulating substrate may have a conductive layer or an adhesive layer or the like between each of the layers. The antenna substrate may also have an interlayer conductive section. The conductive layer has, for example, a shape such as a power supply pattern, a grounding pattern or a wiring pattern. The material for the conductive layer and the interlayer conductive section may be, for example, copper, aluminum, gold, silver, or an alloy of these metals.

The antenna substrate may be, for example, a printed wiring board having a transmission line (microstrip line, slot line, or coplanar line or the like), a power supply circuit, a through hole, or a via or the like formed thereon.

In a number of embodiments, the antenna substrate is used for mounting a plurality of antenna elements on the substrate. In a number of embodiments, the antenna substrate is used for mounting an antenna device on the substrate.

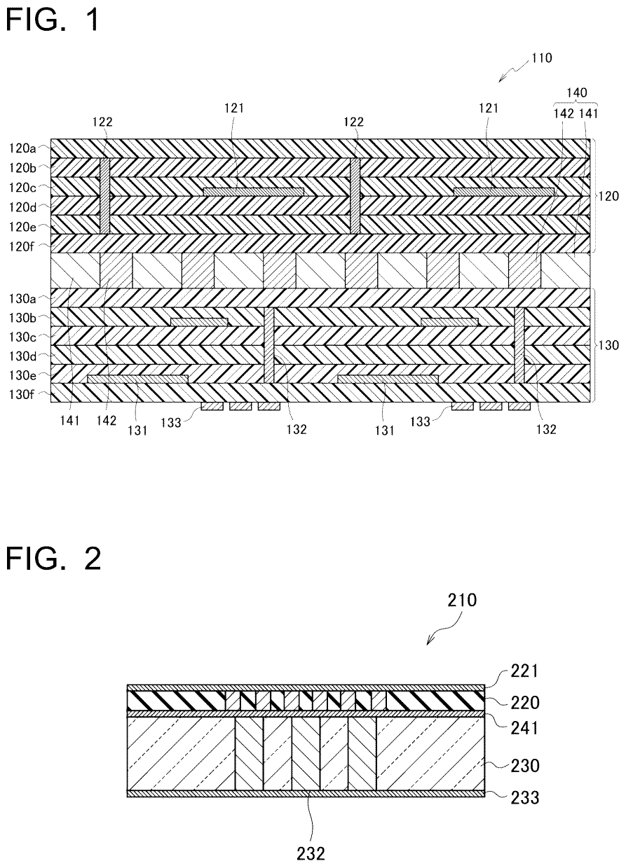

FIG. 1 illustrates one example of an antenna substrate. The antenna substrate 110 is a composite printed board having a printed wiring board 120 and a printed wiring board 130.

The printed wiring board 120 is a multilayer printed wiring board having a plurality of polyimide material layers. The polyimide material layers 120a, 120b, 120c, 120d, 120e and 120f may be layers of the same composition or layers with differing compositions. The printed wiring board 120 may have an adhesive layer between adjacent polyimide material layers. The printed wiring board 120 has a conductive layer 121 and an interlayer conductive section 122. An antenna element is mounted on the surface of the printed wiring board 120 on the side of the polyimide material layer 120a. The printed wiring board 120 has a conductive layer (not shown in the drawing) on the surface on the side of the polyimide material layer 120a, and this conductive layer may have a conductive layer having a wiring pattern shape, and a conductive layer having a pattern shaped to connect with the antenna element. The printed wiring board 120 may also have a conductive layer on the surface of the polyimide material layer 120f.

The printed wiring board 130 is a multilayer printed board having a plurality of insulating layers. The insulating layers 130a, 130b, 130c, 130d, 130e and 130f may be layers of the same composition or layers with differing compositions. The insulating layers may be polyimide material layers, or insulating layers other than a polyimide material layer. The printed wiring board 130 may have an adhesive layer between adjacent insulating layers. The printed wiring board 130 has an interlayer conductive section 132 and a conductive layer 131. A semiconductor element is mounted on the surface of the printed wiring board 130 on the side of the insulating layer 130f. The printed wiring board 130 has a conductive layer on the surface of the insulating layer 130f, and this conductive layer may have a conductive layer (not shown in the drawing) having a wiring pattern shape, and a conductive layer 133 having a pattern shaped to connect with the semiconductor element. The printed wiring board 130 may also have a conductive layer on the surface of the insulating layer 130a.

In the printed wiring board 120, at least a portion of the plurality polyimide material layers may be insulating layers other than polyimide material layers. In such cases, at least the polyimide material layer closest to the mounting section for the antenna element (namely, the polyimide material layer 120a) may be a polyimide material layer. In FIG. 1, an example in which the printed wiring board 120 has a plurality of polyimide material layers is illustrated, but another example of the printed wiring board 120 is a printed wiring board having a single polyimide material layer. In FIG. 1, a composite printed wiring board having two printed wiring boards is illustrated as the antenna substrate 110, but other examples of the antenna substrate include antenna substrates having either one printed wiring board, or three or more printed wiring boards.

FIG. 2 illustrates one example of an antenna substrate. The antenna substrate 210 has a single printed wiring board.

The antenna substrate 210 has an insulating layer 220, an insulating layer 230, conductive layers 221, 241 and 233, and a via 232. A power amplifier is mounted on the surface of the conductive layer 221, and an antenna element is mounted on the side surface of the antenna substrate 210.

### <Antenna Device>

An antenna device has the antenna substrate of an embodiment described above, and an antenna element positioned on one surface of the substrate. The antenna element may be a patch antenna (also known as a “microstrip antenna”). The antenna device may be an array antenna device having antenna elements positioned in an array. The array antenna device may be a phased array antenna device, and can be used in beamforming technology.

In a number of embodiments, the antenna device is an antenna module containing the antenna substrate of an embodiment described above, an antenna positioned on one surface of the substrate, and a radio frequency integrated circuit (RF-IC) positioned on the other surface of the substrate. The antenna device may also contain other components included in typical antenna devices. Examples of these other components include switches, power amplifiers, low-noise amplifiers, attenuators, phase shifters, signal combiners/splitters, mixers, and amplification circuits.

The antenna module contains either one, or two or more antennas. For example, the antenna module may be a module containing only a single array antenna, or may be a multi-array antenna module containing a plurality of array antennas. The antenna module may be a multi-band antenna module that can be used in a plurality of frequency bands. In those cases where the antenna is operated across a plurality of frequency bands, the organic material is preferably a material that exhibits little variation in dielectric characteristics across a wide frequency band, as well as excellent dimensional stability. For example, by using a multi-band antenna module containing only a single array antenna, a reduction in the size of the module can be achieved.

Examples of the form of the antenna device include AiB (Antenna in Board) and AiP (Antenna in Package). In either form, from the viewpoint of suppressing transmission loss to a low level, the polyimide material contained in the antenna substrate preferably has a low dielectric constant and dielectric loss tangent, and a small coefficient of thermal expansion.

### <Radio Unit, Radio Substation>

The antenna device may be used, for example, in a radio unit (RU), radio substation, base station, user terminal, communication device, or communication system or the like. A number of embodiments provide an RU, radio substation, smart phone, or advanced driver-assistance system (ADAS) or the like containing the antenna device of an embodiment described above.

### EXAMPLES OF EMBODIMENTS

Examples of embodiments of the present invention are described below. However, the present invention is not limited to the following embodiments.
[1] An antenna substrate material containing a block copolymer, wherein the block copolymer contains a polyimide block (BI) and a polyamic acid block (BA).
[2] The antenna substrate material according to [1] above, wherein the block copolymer contains a structural unit (X) having a group (X) containing at least one non-aromatic hydrocarbon group.
[3] The antenna substrate material according to [1] or [2] above, wherein the block copolymer contains a structural unit (Y) having a group (Y) containing at least one aromatic cyclic group.
[4] An antenna substrate material containing a block copolymer, wherein the block copolymer contains a polyimide block (BI) and a polyamic acid block (BA), and contains a structural unit represented by formula (I) shown above and a structural unit represented by formula (A) shown above, wherein at least R^{A} described above and R^{C} described above are different, or at least R^{B} described above and R^{D} described above are different.
[5] The antenna substrate material according to [4] above, wherein the block copolymer contains at least one type of structural unit selected from the group consisting of structural units represented by formula (XI) shown above and structural units represented by formula (XA) shown above.
[6] The antenna substrate material according to [4] or [5] above, wherein the block copolymer contains at least one type of structural unit selected from the group consisting of structural units represented by formula (YI) shown above and structural units represented by formula (YA) shown above.
[7] The antenna substrate material according to any one of [4] to [6] above, wherein the block copolymer contains at least one type of structural unit selected from the group consisting of structural units represented by formula (XI) shown above (provided that at least one of R¹ and R² is the group (X) described above, wherein the total number of carbon atoms in the at least one non-aromatic hydrocarbon group is 9 or more), and structural units represented by formula (XA) shown above (provided that at least one of R³ and R⁴ is the group (X) described above, wherein the total number of carbon atoms in the at least one non-aromatic hydrocarbon group is 9 or more).
[8] The antenna substrate material according to any one of [4] to [7] above, wherein the block copolymer contains at least one type of structural unit selected from the group consisting of structural units represented by formula (YI) shown above (provided that R⁵ and R⁶ each independently represent a group containing an aromatic hydrocarbon group), and structural units represented by formula (YA) shown above (provided that R⁷ and R⁸ each independently represent a group containing an aromatic hydrocarbon group).
[9] The antenna substrate material according to any one of [4] to [8] above, wherein the polyimide block (BI) contains a structural unit represented by formula (XI) shown above.
[10] The antenna substrate material according to any one of [4] to [9] above, wherein the polyamic acid block (BA) contains a structural unit represented by formula (YA) shown above.
[11] The antenna substrate material according to any one of [4] to [10] above, wherein the block copolymer contains a structural unit represented by formula (XI) shown above (wherein R¹ represents the group (X)), and a structural unit represented by formula (YA) shown above (wherein R⁷ represents a group containing an aromatic hydrocarbon group).
[12] The antenna substrate material according to any one of [4] to [11] above, wherein the block copolymer contains a structural unit represented by formula (YI) shown above (wherein R⁵ represents a group containing an aromatic hydrocarbon group), and a structural unit represented by formula (XA) shown above (wherein R³ represents the group (X)).
[13] An antenna substrate material containing a block copolymer, wherein the block copolymer contains a polyimide block (BI) and a polyamic acid block (BA), and has a structure derived from a diamine or diisocyanate, and a structure derived from a tetracarboxylic dianhydride.
[14] The antenna substrate material according to [13] above, wherein at least one of the structure derived from a diamine or diisocyanate and the structure derived from a tetracarboxylic dianhydride includes a structure having a group (X) containing at least one non-aromatic hydrocarbon group.
[15] The antenna substrate material according to [13] or [14] above, wherein the structure derived from a diamine or diisocyanate and the structure derived from a tetracarboxylic dianhydride include a structure having a group (Y) containing at least one aromatic cyclic group.
[16] The antenna substrate material according to any one of [13] to [15] above, wherein at least one of the structure derived from a diamine or diisocyanate and the structure derived from a tetracarboxylic dianhydride includes a structure having a group (X) containing at least one non-aromatic hydrocarbon group, wherein the total number of carbon atoms in the at least one non-aromatic hydrocarbon group is 9 or more.
[17] The antenna substrate material according to any one of [13] to [16] above, wherein the structure derived from a diamine or diisocyanate and the structure derived from a tetracarboxylic dianhydride include a structure having a group (Y) containing at least one aromatic cyclic group, wherein the aromatic cyclic group is an aromatic hydrocarbon group.
[18] The antenna substrate material according to any one of [13] to [17] above, wherein the structure derived from a diamine or diisocyanate contained in the polyimide block (BI) includes a structure derived from a diamine or diisocyanate having a group (X) containing at least one non-aromatic hydrocarbon group.
[19] The antenna substrate material according to any one of [13] to [18] above, wherein the structure derived from a diamine or diisocyanate contained in the polyamic acid block (BA) includes a structure derived from a diamine or diisocyanate having a group (Y) containing at least one aromatic cyclic group.
[20] The antenna substrate material according to any one of [13] to [19] above, wherein the structure derived from a diamine or diisocyanate includes a structure derived from a diamine or diisocyanate having a group (X) containing at least one non-aromatic hydrocarbon group, wherein the total number of carbon atoms in the at least one non-aromatic hydrocarbon group is 9 or more, and a structure derived from a diamine or diisocyanate having a group (Y) containing at least one aromatic cyclic group, wherein the aromatic cyclic group is an aromatic hydrocarbon group.
[21] The antenna substrate material according to any one of [13] to [20] above, wherein the block copolymer contains a structure derived from a dimer diamine or dimer diisocyanate.
[22] The antenna substrate material according to any one of [1] to [21] above, wherein the at least one non-aromatic hydrocarbon group is a saturated aliphatic hydrocarbon group, unsaturated aliphatic hydrocarbon group, saturated alicyclic hydrocarbon group, unsaturated alicyclic hydrocarbon group, or a group composed of two or more types of groups selected from among these groups.
[23] The antenna substrate material according to any one of [1] to [22] above, wherein the group (X) is a saturated aliphatic hydrocarbon group, unsaturated aliphatic hydrocarbon group, saturated alicyclic hydrocarbon group, unsaturated alicyclic hydrocarbon group, or a group composed of two or more types of groups selected from among a saturated aliphatic hydrocarbon group, unsaturated aliphatic hydrocarbon group, saturated alicyclic hydrocarbon group and unsaturated alicyclic hydrocarbon group.
[24] The antenna substrate material according to any one of [1] to [23] above, wherein the total number of carbon atoms within saturated aliphatic hydrocarbon groups and unsaturated aliphatic hydrocarbon groups contained in the group (X) is greater than the total number of carbon atoms within saturated alicyclic hydrocarbon groups and unsaturated alicyclic hydrocarbon groups contained in the group (X).
[25] The antenna substrate material according to any one of [1] to [24] above, wherein the group (X) contains a saturated alicyclic hydrocarbon group.
[26] The antenna substrate material according to any one of [1] to [25] above, wherein the group (X) does not contain an aromatic cyclic group.
[27] The antenna substrate material according to any one of [1] to [26] above, wherein the group (X) contains a linear saturated aliphatic hydrocarbon group of 6 or more carbon atoms.
[28] The antenna substrate material according to any one of [1] to [27] above, wherein the total number of carbon atoms in the at least one non-aromatic hydrocarbon group is 16 or more.
[29] The antenna substrate material according to any one of [1] to [28] above, wherein the total number of carbon atoms in the at least one non-aromatic hydrocarbon group is 28 or more.
[30] The antenna substrate material according to any one of [1] to [29] above, for use in a multi-band antenna.
[31] The antenna substrate material according to any one of [1] to [30] above, for use in a patch antenna.
[32] The antenna substrate material according to any one of [1] to [31] above, wherein
   when a film is produced using the antenna substrate material, and the relative dielectric constant and dielectric loss tangent of the film at a frequency of 10 GHz and the coefficient of thermal expansion of the film are measured,
   the relative dielectric constant is not more than 3.5, the dielectric loss tangent is not more than 0.0100, and the coefficient of thermal expansion is not more than 80 ppm/K.
[33] The antenna substrate material according to any one of [1] to [32] above, wherein
   when a film is produced using the antenna substrate material, and the relative dielectric constant and dielectric loss tangent of the film at frequencies of 10 GHz and 100 GHz are measured,
   each relative dielectric constant is not more than 3.5, and each dielectric loss tangent is not more than 0.0100.
[34]A method for manufacturing the antenna substrate material according to any one of [1] to [33] above, the method including:
   obtaining a polyimide (PI) using a diamine or diisocyanate and a tetracarboxylic dianhydride,
   obtaining a polyamic acid (PA) using a diamine and a tetracarboxylic dianhydride, and
   obtaining a block copolymer using the polyimide (PI) and the polyamic acid (PA).
[35] An antenna substrate material composition containing the antenna substrate material according to any one of [1] to [33] above, and a solvent.

The disclosure of the present application is related to the subject matter disclosed in PCT/JP2024/003168 filed on Jan. 31, 2024, the entire disclosed content of which is incorporated herein by reference.

### EXAMPLES

Embodiments of the present invention are described below in further detail using a series of examples. However, embodiments of the present invention are not limited to the following examples.

### <Synthesis of Polyimides (PI) and Polyamic Acids (PA)>

### [Polyimide (PI-1)]

First, 35.5 g (0.066 mol) of a dimer diamine (PRIAMINE 1075, manufactured by Croda Japan Co., Ltd., contains the dimer diamine represented by the formula shown below) (hereinafter abbreviated as DDA) was dissolved in 205.6 g of N-methylpyrrolidone and 30.8 g of xylene to obtain a diamine solution. Subsequently, 28.5 g (0.088 mol) of 3,3′,4,4′-benzophenonetetracarboxylic dianhydride (hereinafter abbreviated as BTDA) was added to the diamine solution, and a reaction was conducted until a uniform transparent solution was obtained. The reaction was conducted by stirring the solution at not more than 50° C. for at least one hour. Subsequently, the transparent solution was stirred at 180° C. for at least 4 hours to conduct a thermal dehydration-imidization reaction, yielding a solution (varnish) of a polyimide (PI-1) having acid anhydride structures derived from the BTDA at the terminals. The number average molecular weight of the polyimide (PI-1) was 3,000.

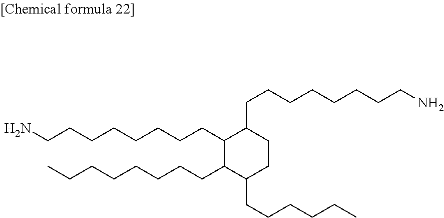 [SMILES: CCCCCCCCC1C(CCCCCC)CCC(CCCCCCCCN)C1CCCCCCCCN]

### [Polyimides (PI-2) to (PI-6)]

With the exception of using the diamines and tetracarboxylic dianhydrides shown in Table 2, solutions of polyimides (PI-2) to (PI-6) were obtained in the same manner as the polyimide (PI-1).

### [Polyamic Acid (PA-1)]

First, 57.3 g (0.155 mol) of 4,4′-bis(4-aminophenoxy)biphenyl (hereinafter abbreviated as BODA) was dissolved in 235.6 g of N,N′-dimethylacetamide and 167.9 g of N-methylpyrrolidone to obtain a diamine solution. Subsequently, 38.7 g (0.132 mol) of 3,3′,4,4′-biphenyltetracarboxylic dianhydride (hereinafter abbreviated as BPDA) was added to the diamine solution and reacted, yielding a solution of a polyamic acid (polyimide precursor) (PA-1) having amine structures derived from the BODA at the terminals. The reaction was conducted by stirring the solution at not more than 50° C. for at least 8 hours. The number average molecular weight of the polyamic acid (PA-1) was 4,000.

### [Polyamic Acids (PA-2) to (PA-6)]

With the exception of using the diamines and tetracarboxylic dianhydrides shown in Table 2, solutions of polyamic acids (PA-2) to (PA-6) were obtained in the same manner as the polyamic acid (PA-1).

### <Synthesis of Block Copolymers (Block Polyamic Acid Imides)>

### Example 1

First, 300.4 g of the solution of the polyimide (PI-1) and 499.6 g of the solution of the polyamic acid (PA-1) were mixed together and reacted, yielding a varnish of a block polyamic acid imide 1. The reaction was conducted by stirring the solution at not more than 100° C. for at least one hour. The number average molecular weight of the block polyamic acid imide 1 was 30,000. The concentration of the block polyamic acid imide 1, based on the mass of the varnish, was 20% by mass. The block copolymer (block polyamic acid imide) corresponds with an antenna substrate material, and the varnish is a composition containing the block copolymer and a solvent.

### Examples 2 to 9

With the exception of using solutions of the polyimides and polyamic acids shown in Table 2, varnishes of block polyamic acid imides 2 to 9 were obtained in the same manner as Example 1.

### <Synthesis of Polyamic Acids>

### Comparative Example 1

First, 76.6 g (0.38 mol) of 4,4′-diaminodiphenyl ether (hereinafter abbreviated as ODA) was dissolved in 640.0 g of N,N′-dimethylacetamide to obtain a diamine solution. Subsequently, 81.8 g (0.38 mol) of pyromellitic dianhydride (hereinafter abbreviated as PIMDA) was added to the diamine solution and reacted, yielding a varnish of a polyamic acid 1 (polyimide precursor). The reaction was conducted by stirring the solution at not more than 50° C. for at least 8 hours.

### Comparative Example 2

With the exception of using the diamine and tetracarboxylic dianhydride shown in Table 3, a varnish of a polyamic acid 2 was obtained in the same manner as Comparative Example 1.

Tables 2 and 3 show the types and amounts of the diamines and tetracarboxylic dianhydrides used in the syntheses of the polyimides and polyamic acids, and the types and amounts of the polyimides and polyamic acids used in the syntheses of the block polyamic acid imides. Further, Tables 2 and 3 also show the number average molecular weight of each polyimide and polyamic acid. The number average molecular weights were measured in accordance with the method described below.

The meanings of the abbreviations used in Tables 2 and 3 are shown below.
BTDA: 3,3′,4,4′-benzophenonetetracarboxylic dianhydride
BPDA: 3,3′,4,4′-biphenyltetracarboxylic dianhydride
PMDA: pyromellitic dianhydride
TAHQ: bis(1,3-dioxo-1,3-dihydroisobenzofuran-5-carboxylic acid)-1,4-phenylene
DDA: dimer diamine
BODA: 4,4′-bis(4-aminophenoxy)biphenyl
PPD: p-phenylenediamine
ODA: 4,4′-diaminodiphenyl ether
rn-TB: rn-tolidine (4,4′-diarnino-2,2′-dirnethylbiphenyl)

TABLE 2

| | | | | Example 1 | | Example 2 | | Example 3 | |
|---|---|---|---|---|---|---|---|---|---|
| | | | | Mass | Content | Mass | Content | Mass | Content |
| | | | | (g) | (mass %) | (g) | (mass %) | (g) | (mass %) |
| Polyimide | Acid | BTDA | Organic | 28.5 | 17.8 | 35.6 | 22.3 | 42.8 | 26.7 |
| block | anhydride | | group (Y) | | | | | | |
| | Diamine | DDA | Group (X) | 35.5 | 22.2 | 44.4 | 27.7 | 53.2 | 33.3 |
| Polyamic | Acid | BPDA | Organic | 38.7 | 24.2 | 30.7 | 19.2 | 22.7 | 14.2 |
| acid block | anhydride | | group (Y) | | | | | | |
| | | PMDA | Organic | — | — | — | — | — | — |
| | | | group (Y) | | | | | | |
| | | TAHQ | Organic | — | — | — | — | — | — |
| | | | group (Y) | | | | | | |
| | Diamine | BODA | Organic | 57.3 | 35.8 | 49.3 | 30.8 | 41.3 | 25.8 |
| | | | group (Y) | | | | | | |
| | | PPD | Organic | — | — | — | — | — | — |
| | | | group (Y) | | | | | | |
| | | ODA | Organic | — | — | — | — | — | — |
| | | | group (Y) | | | | | | |
| | | m-TB | Group (X)/ | — | — | — | — | — | — |
| | | | organic | | | | | | |
| | | | group (Y) | | | | | | |
| Polyimide | Relative | Frequency | 10 | 2.9 | | 2.8 | | 2.8 | |
| | dielectric | (GHz) | 30 | 2.9 | | 2.8 | | 2.8 | |
| | constant | | 50 | 2.9 | | 2.8 | | 2.8 | |
| | (Dk) | | 100 | 2.9 | | 2.8 | | 2.8 | |
| | Dielectric | Frequency | 10 | 0.0028 | | 0.0015 | | 0.0021 | |
| | loss | (GHz) | 30 | 0.0034 | | 0.0019 | | 0.0026 | |
| | tangent | | 50 | 0.0038 | | 0.0019 | | 0.0031 | |
| | (Df) | | 100 | 0.0049 | | 0.0025 | | 0.0038 | |
| | Coefficient of linear thermal | | | 39 | | 58 | | 60 | |
| | expansion (ppm/K) | | | | | | | | |
| | Glass transition temperature | | | 394 | | 383 | | 355 | |
| | (° C.) | | | | | | | | |
| | Copper foil adhesion | | | — | | 10 | | 12 | |
| | (N/cm) | | | | | | | | |
| | | | | Example 4 | | Example 5 | | Example 6 | |
| | | | | Mass | Content | Mass | Content | Mass | Amount |
| | | | | (g) | (mass %) | (g) | (mass %) | (g) | (mass %) |
| Polyimide | Acid | BTDA | Organic | 35.6 | 28.5 | 35.6 | 25.9 | 35.6 | 23.4 |
| block | anhydride | | group (Y) | | | | | | |
| | Diamine | DDA | Group (X) | 44.4 | 35.4 | 44.4 | 32.3 | 44.4 | 29.2 |
| Polyamic | Acid | BPDA | Organic | 30.7 | 24.5 | 30.7 | 22.3 | — | — |
| acid block | anhydride | | group (Y) | | | | | | |
| | | PMDA | Organic | — | — | — | — | 22.8 | 15.0 |
| | | | group (Y) | | | | | | |
| | | TAHQ | Organic | — | — | — | — | — | — |
| | | | group (Y) | | | | | | |
| | Diamine | BODA | Organic | — | — | — | — | 49.3 | 32.4 |
| | | | group (Y) | | | | | | |
| | | PPD | Organic | 14.5 | 11.6 | — | — | — | — |
| | | | group (Y) | | | | | | |
| | | ODA | Organic | — | — | 26.8 | 19.5 | — | — |
| | | | group (Y) | | | | | | |
| | | m-TB | Group (X)/ | — | — | — | — | — | — |
| | | | organic | | | | | | |
| | | | group (Y) | | | | | | |
| Polyimide | Relative | Frequency | 10 | 2.7 | | 2.8 | | 2.8 | |
| | dielectric | (GHz) | 30 | 2.7 | | 2.8 | | 2.8 | |
| | constant | | 50 | 2.7 | | 2.8 | | 2.8 | |
| | (Dk) | | 100 | 2.7 | | 2.8 | | 2.8 | |
| | Dielectric | Frequency | 10 | 0.0021 | | 0.0021 | | 0.0014 | |
| | loss | (GHz) | 30 | 0.0024 | | 0.0025 | | 0.0018 | |
| | tangent | | 50 | 0.0028 | | 0.0030 | | 0.0023 | |
| | (Df) | | 100 | 0.0033 | | 0.0038 | | 0.0027 | |
| | Coefficient of linear thermal | | | 7 | | 85 | | 70 | |
| | expansion (ppm/K) | | | | | | | | |
| | Glass transition temperature | | | 379 | | 228 | | 444 | |
| | (° C.) | | | | | | | | |
| | Copper foil adhesion | | | 9 | | — | | 9 | |
| | (N/cm) | | | | | | | | |
| | | | | Example 7 | | Example 8 | | Example 9 | |
| | | | | Mass | Amount | Mass | Amount | Mass | Amount |
| | | | | (g) | (mass %) | (g) | (mass %) | (g) | (mass %) |
| Polyimide | Acid | BTDA | Organic | 46.1 | 25.6 | 58.9 | 32.7 | 42.2 | 26.4 |
| block | anhydride | | group (Y) | | | | | | |
| | Diamine | DDA | Group (X) | 57.4 | 31.9 | 82.3 | 45.7 | 51.0 | 31.8 |
| Polyamic | Acid | BPDA | Organic | 39.8 | 22.1 | 18.9 | 10.5 | 20.4 | 12.8 |
| acid block | anhydride | | group (Y) | | | | | | |
| | | PMDA | Organic | — | — | — | — | — | — |
| | | | group (Y) | | | | | | |
| | | TAHQ | Organic | — | — | — | — | 16.1 | 10.1 |
| | | | group (Y) | | | | | | |
| | Diamine | BODA | Organic | — | — | — | — | — | — |
| | | | group (Y) | | | | | | |
| | | PPD | Organic | — | — | — | — | — | — |
| | | | group (Y) | | | | | | |
| | | ODA | Organic | — | — | — | — | — | — |
| | | | group (Y) | | | | | | |
| | | m-TB | Group (X)/ | 36.8 | 20.4 | 19.9 | 11.1 | 30.3 | 19.0 |
| | | | organic | | | | | | |
| | | | group (Y) | | | | | | |

| | | | | | | |
|---|---|---|---|---|---|---|
| Polyimide | Relative | Frequency | 10 | 2.7 | 2.7 | 2.5 |
| | dielectric | (GHz) | 30 | 2.7 | 2.7 | 2.5 |
| | constant | | 50 | 2.7 | 2.7 | 2.5 |
| | (Dk) | | 100 | 2.7 | 2.7 | 2.5 |
| | Dielectric | Frequency | 10 | 0.0009 | 0.0010 | 0.0011 |
| | loss | (GHz) | 30 | 0.0011 | 0.0009 | 0.0020 |
| | tangent | | 50 | 0.0012 | 0.0011 | 0.0020 |
| | (Df) | | 100 | 0.0015 | 0.0015 | 0.0032 |

| | | | |
|---|---|---|---|
| Coefficient of linear thermal | 33 | −214 | 27 |
| expansion (ppm/K) | | | |
| Glass transition temperature | 386 | 305 | 346 |
| (° C.) | | | |
| Copper foil adhesion | 11 | 11 | 10 |
| (N/cm) | | | |

TABLE 3

| | | | | Comparative | | Comparative | |
|---|---|---|---|---|---|---|---|
| | | | | Example 1 | | Example 2 | |
| | | | | Mass | Amount | Mass | Amount |
| | | | | (g) | (mass %) | (g) | (mass %) |
| Polyamic | Acid anhydride | PMDA | Organic group (Y) | 81.8 | 51.6 | — | — |
| acid | | BTDA | Organic group (Y) | — | — | 59.0 | 36.9 |
| | Diamine | ODA | Organic group (Y) | 76.6 | 48.4 | — | — |
| | | DDA | Group (X) | — | — | 101.0 | 63.1 |

| | | | | | |
|---|---|---|---|---|---|
| Polyimide | Relative dielectric | Frequency | 10 | — | 2.5 |
| | constant | (GHz) | 30 | 3.0 | 2.5 |
| | (Dk) | | 50 | 3.0 | 2.5 |
| | | | 100 | 3.0 | 2.5 |
| | Dielectric loss | Frequency | 10 | — | 0.0017 |
| | tangent | (GHz) | 30 | 0.0104 | 0.0016 |
| | (Df) | | 50 | 0.0108 | 0.0017 |
| | | | 100 | 0.0119 | 0.0020 |

| | | |
|---|---|---|
| Coefficient of linear thermal expansion | 38 | >100 |
| (ppm/K) | | |
| Glass transition temperature | 385 | — |
| (° C.) | | |
| Copper foil adhesion | — | — |
| (N/cm) | | |

### (Number Average Molecular Weight)

Number average molecular weights (Mn) were measured by gel permeation chromatography (GPC), and calculated using a calibration curve of standard polystyrenes. The calibration curve was approximated as a cubic equation using a five-sample set of standard polystyrenes (TSK Standard Polystyrenes, manufactured by Tosoh Corporation). The GPC conditions were as follows.
GPC apparatus: High-speed GPC apparatus HLC-8320GPC (manufactured by Tosoh Corporation)
Detector: Ultraviolet absorption detector UV-8320 (manufactured by Tosoh Corporation)
Columns: Gelpack GL-S300MIDT-5 (two columns) (manufactured by Resonac K.K.)
Eluent: THF/DMF=1/1 (volumetric ratio)+LiBr (0.06 mol/L)+H₃PO₄ (0.06 mol/L)
Flow rate: 1 mL/minute
Column size: 8 mm I.D.×300 mm
Sample concentration: 5 mg/1 mL
Injection volume: 5 μL
Measurement temperature: 40° C.

<Production of Films>

### Example 1

Using the obtained varnish (composition), a film was produced in accordance with the method described below.

The surface of a commercially available glass substrate was degreased with acetone, and a film applicator fitted with a film thickness adjustment function was used to apply the varnish of the block polyamic acid imide 1 so as to achieve a film thickness following imidization of 100 μm. The applied varnish was subjected to preliminary drying at 80° C. for 30 minutes using a hot plate, thus forming a layer of the block polyamic acid imide 1. Subsequently, the layer of the block polyamic acid imide 1 was heated under a nitrogen atmosphere in an inert gas oven at 350° C. for 30 minutes to obtain a film of the block polyimide 1. The glass substrate with the film formed thereon was immersed for about 15 minutes in warm water, thereby separating the film from the glass substrate and completing production of a film with a thickness of 100 μm.

With the exception of conducting the application of the varnish of the block polyamic acid imide 1 so as to achieve a film thickness following imidization of 25 μm, a film with a thickness of 25 μm was also produced.

### Examples 2 to 9 and Comparative Examples 1 and 2

With the exception of replacing the varnish of the block polyamic acid imide 1 with each of the varnishes obtained in Examples 2 to 9 and Comparative Examples 1 and 2, films were obtained in the same manner as described above.

### <Film Evaluations>

Using the methods described below, the characteristics of the films produced using the varnishes of Examples 1 to 9 and Comparative Examples 1 and 2 were evaluated. The evaluation results are shown in Tables 2 and 3.

### (Relative Dielectric Constant and Dielectric Loss Tangent)

The film (of thickness 100 μm) was cut to a size having a diameter of 48 mm, a drying treatment was conducted at 125° C. for one hour, and the film was then left to stand for 24 hours under conditions including a temperature of 23° C. and a relative humidity of 50%. Subsequently, the film dielectric characteristics (the relative dielectric constant Dk and the dielectric loss tangent Df) were measured using a balanced circular disk resonator (BCDR). A PS-XSN-100 device manufactured by Keysight Technologies, Inc. was used for conducting the measurements. The conditions included a frequency of 10 to 100 GHz and a measurement temperature of 25° C.

### (Coefficient of Linear Thermal Expansion (Thermal Expansion Coefficient) and Glass Transition Temperature)

The film (of thickness 25 μm) was cut to produce a test piece having a width of 4 mm and a length of 25 mm. A thermomechanical analyzer (TMA7100 manufactured by Hitachi High-Tech Science Corporation) was used for the measurements. The test piece was heated from room temperature to 350° C. at a rate of temperature increase of 10° C./minute using the tensile test method under conditions including a chuck separation distance of 10 mm and a load of 10 g, and was then cooled to 30° C. at a rate of 10° C./minute. The test piece was then once again heated at a rate of temperature increase of 10° C./minute, the mean coefficient of linear thermal expansion (ppm/° C.) from 30° C. to 200° C. was calculated, and the thus obtained value was deemed the coefficient of linear thermal expansion (ppm/K). Further, the temperature corresponding with the inflection point of the coefficient of linear thermal expansion curve was deemed the glass transition temperature (° C.).

### <Production of Flexible Copper-Clad Laminates (FCCL)>

### Example 1

The obtained varnish (composition) was used to produce a flexible copper-clad laminate (FCCL) in accordance with the method described below.

Using a film applicator fitted with a film thickness adjustment function, the varnish of the block polyamic acid imide 1 was applied to the matte surface of a low-roughness copper foil having a surface roughness (Rz_{JIS}) of 1.2 μm so as to achieve a film thickness following imidization of 25 μm. The applied varnish was subjected to preliminary drying at 80° C. for 30 minutes using a hot plate, thus forming a layer of the block polyamic acid imide 1. Subsequently, the copper foil with the layer of the block polyamic acid imide 1 formed thereon was heated under a nitrogen atmosphere in an inert gas oven at 350° C. for 30 minutes, thus obtaining a FCCL having a layer of the block polyimide 1.

### Examples 2 to 9 and Comparative Examples 1 and 2

With the exception of replacing the varnish of the block polyamic acid imide 1 with each of the varnishes obtained in Examples 2 to 9 and Comparative Examples 1 and 2, FCCLs were obtained in the same manner as described above.

### <FCCL Evaluation>

Using the method described below, the adhesion of the block polyimide was evaluated for each of the FCCLs produced using the varnishes of Examples 1 to 9 and Comparative Examples 1 and 2. The evaluation results are shown in Tables 2 and 3.

### (90° Peel Strength)

The copper foil of each FCCL was processed by etching to form straight lines of width 5 mm. A material tester (small tabletop tester EZ-S50N manufactured by Shimadzu Corporation) was then used to measure the peel strength when the copper foil that had been processed into straight lines was peeled from the block polyimide layer in a 90° direction relative to the in-plane direction of the block polyimide layer. The peel speed was set to 50 mm/minute.

### DESCRIPTION OF THE REFERENCE SYMBOLS

110: Antenna substrate
120: Printed wiring board
120a to 120f: Polyimide material layer
121: Conductive layer
122: Interlayer conductive section
130: Printed wiring board
130a to 130f: Insulating layer
131: Conductive layer
132: Interlayer conductive section
133: Conductive layer
140: Connection section
141: Insulating layer
142: Conductive section
210: Antenna substrate
220: Insulating layer
221: Conductive layer
222: Conductive section
230: Insulating layer
232: Conductive section
233: Conductive layer
241: Conductive layer

1. An antenna substrate material comprising a block copolymer, wherein the block copolymer contains a polyimide block (BI) and a polyamic acid block (BA).

2. The antenna substrate material according to claim 1, wherein the block copolymer contains a structural unit (X) having a group (X) containing at least one non-aromatic hydrocarbon group.

3. The antenna substrate material according to claim 2, wherein the block copolymer contains a structural unit (Y) having a group (Y) containing at least one aromatic cyclic group.

4. An antenna substrate material comprising a block copolymer, wherein the block copolymer contains a polyimide block (BI) and a polyamic acid block (BA), and contains a structural unit represented by a formula (I) shown below and a structural unit represented by a formula (A) shown below, wherein at least R^{A} described below and R^{C} described below are different, or at least R^{B} described below and R^{D} described below are different: 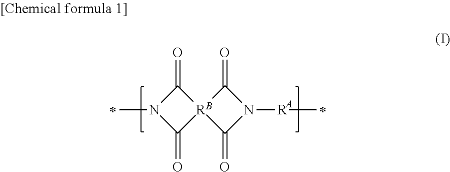
(wherein in the formula, R^{A} and R^{B} each independently represent an organic group); 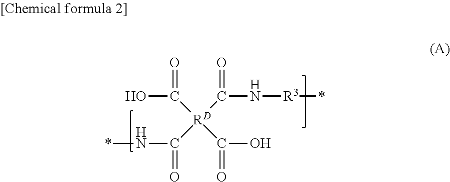
(wherein in the formula, R^{C} and R^{D} each independently represent an organic group).

5. The antenna substrate material according to claim 4, wherein the block copolymer contains at least one type of structural unit selected from the group consisting of structural units represented by a formula (XI) shown below and structural units represented by a formula (XA) shown below: 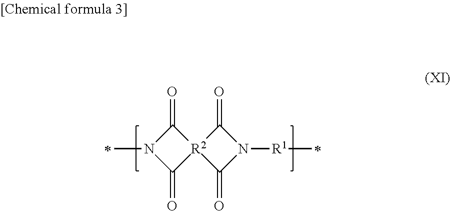
(wherein in the formula, R¹ and R² each independently represent an organic group, and at least one of R¹ and R² represents a group (X) containing at least one non-aromatic hydrocarbon group); 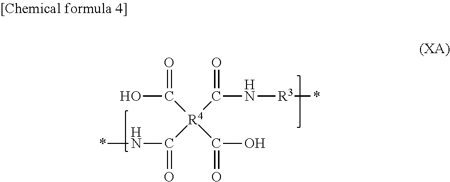
(wherein in the formula, R³ and R⁴ each independently represent an organic group, and at least one of R³ and R⁴ represents a group (X) containing at least one non-aromatic hydrocarbon group).

6. The antenna substrate material according to claim 5, wherein the block copolymer contains at least one type of structural unit selected from the group consisting of structural units represented by a formula (YI) shown below and structural units represented by a formula (YA) shown below: 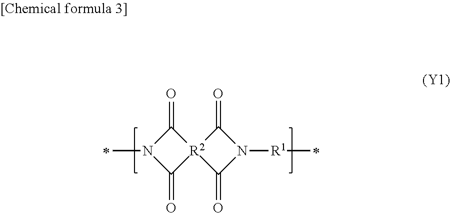
(wherein in the formula, R⁵ and R⁶ each independently represent a group (Y) containing at least one aromatic cyclic group); 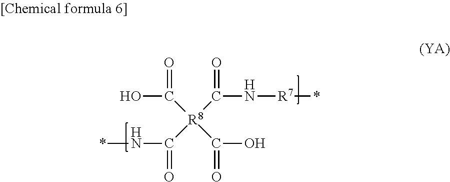
(wherein in the formula, R⁷ and R⁸ each independently represent a group (Y) containing at least one aromatic cyclic group).

7. The antenna substrate material according to claim 5, wherein the block copolymer contains at least one type of structural unit selected from the group consisting of structural units represented by the formula (XI) (provided that at least one of R¹ and R² is the group (X), wherein a total number of carbon atoms in the at least one non-aromatic hydrocarbon group is 9 or more), and structural units represented by the formula (XA) (provided that at least one of R³ and R⁴ is the group (X), wherein a total number of carbon atoms in the at least one non-aromatic hydrocarbon group is 9 or more).

8. The antenna substrate material according to claim 6, wherein the block copolymer contains at least one type of structural unit selected from the group consisting of structural units represented by the formula (YI) (provided that R⁵ and R⁶ each independently represent a group containing an aromatic hydrocarbon group), and structural units represented by the formula (YA) (provided that R⁷ and R⁸ each independently represent a group containing an aromatic hydrocarbon group).

9. The antenna substrate material according to claim 5, wherein the polyimide block (BI) contains a structural unit represented by the formula (XI).

10. The antenna substrate material according to claim 6, wherein the polyamic acid block (BA) contains a structural unit represented by the formula (YA).

11. The antenna substrate material according to claim 6, wherein the block copolymer contains a structural unit represented by the formula (XI) (wherein R¹ represents the group (X)), and a structural unit represented by the formula (YA) (wherein R⁷ represents a group containing an aromatic hydrocarbon group).

12. The antenna substrate material according to claim 6, wherein the block copolymer contains a structural unit represented by the formula (YI) (wherein R⁵ represents a group containing an aromatic hydrocarbon group), and a structural unit represented by the formula (XA) (wherein R³ represents the group (X)).

13. An antenna substrate material comprising a block copolymer, wherein the block copolymer contains a polyimide block (BI) and a polyamic acid block (BA), and has a structure derived from a diamine or diisocyanate, and a structure derived from a tetracarboxylic dianhydride.

14. The antenna substrate material according to claim 13, wherein at least one of the structure derived from a diamine or diisocyanate and the structure derived from a tetracarboxylic dianhydride includes a structure having a group (X) containing at least one non-aromatic hydrocarbon group.

15. The antenna substrate material according to claim 14, wherein the structure derived from a diamine or diisocyanate and the structure derived from a tetracarboxylic dianhydride include a structure having a group (Y) containing at least one aromatic cyclic group.

16. The antenna substrate material according to claim 13, wherein at least one of the structure derived from a diamine or diisocyanate and the structure derived from a tetracarboxylic dianhydride includes a structure having a group (X) containing at least one non-aromatic hydrocarbon group, wherein a total number of carbon atoms in the at least one non-aromatic hydrocarbon group is 9 or more.

17. The antenna substrate material according to claim 16, wherein the structure derived from a diamine or diisocyanate and the structure derived from a tetracarboxylic dianhydride include a structure having a group (Y) containing at least one aromatic cyclic group, wherein the aromatic cyclic group is an aromatic hydrocarbon group.

18. The antenna substrate material according to claim 13, wherein the structure derived from a diamine or diisocyanate contained in the polyimide block (BI) includes a structure derived from a diamine or diisocyanate having a group (X) containing at least one non-aromatic hydrocarbon group.

19. The antenna substrate material according to claim 18, wherein the structure derived from a diamine or diisocyanate contained in the polyamic acid block (BA) includes a structure derived from a diamine or diisocyanate having a group (Y) containing at least one aromatic cyclic group.

20. The antenna substrate material according to claim 13, wherein the structure derived from a diamine or diisocyanate includes a structure derived from a diamine or diisocyanate having a group (X) containing at least one non-aromatic hydrocarbon group, wherein a total number of carbon atoms in the at least one non-aromatic hydrocarbon group is 9 or more, and a structure derived from a diamine or diisocyanate having a group (Y) containing at least one aromatic cyclic group, wherein the aromatic cyclic group is an aromatic hydrocarbon group.

21. The antenna substrate material according to claim 13, wherein the block copolymer contains a structure derived from a dimer diamine or dimer diisocyanate.

22. The antenna substrate material according to claim 2, wherein the at least one non-aromatic hydrocarbon group is a saturated aliphatic hydrocarbon group, an unsaturated aliphatic hydrocarbon group, a saturated alicyclic hydrocarbon group, an unsaturated alicyclic hydrocarbon group, or a group composed of two or more types of groups selected from among these groups.

23. The antenna substrate material according to claim 2, wherein the group (X) is a saturated aliphatic hydrocarbon group, an unsaturated aliphatic hydrocarbon group, a saturated alicyclic hydrocarbon group, an unsaturated alicyclic hydrocarbon group, or a group composed of two or more types of groups selected from among a saturated aliphatic hydrocarbon group, an unsaturated aliphatic hydrocarbon group, a saturated alicyclic hydrocarbon group and an unsaturated alicyclic hydrocarbon group.

24. The antenna substrate material according to claim 2, wherein a total number of carbon atoms within saturated aliphatic hydrocarbon groups and unsaturated aliphatic hydrocarbon groups contained in the group (X) is greater than a total number of carbon atoms within saturated alicyclic hydrocarbon groups and unsaturated alicyclic hydrocarbon groups contained in the group (X).

25. The antenna substrate material according to claim 2, wherein the group (X) contains a saturated alicyclic hydrocarbon group.

26. The antenna substrate material according to claim 2, wherein the group (X) does not contain an aromatic cyclic group.

27. The antenna substrate material according to claim 2, wherein the group (X) contains a linear saturated aliphatic hydrocarbon group of 6 or more carbon atoms.

28. The antenna substrate material according to claim 2, wherein a total number of carbon atoms in the at least one non-aromatic hydrocarbon group is 16 or more.

29. The antenna substrate material according to claim 2, wherein a total number of carbon atoms in the at least one non-aromatic hydrocarbon group is 28 or more.

30. The antenna substrate material according to claim 1, for use in a multi-band antenna.

31. The antenna substrate material according to claim 1, for use in a patch antenna.

32. The antenna substrate material according to claim 1, wherein
when a film is produced using the antenna substrate material, and a relative dielectric constant and dielectric loss tangent of the film at a frequency of 10 GHz, and a coefficient of thermal expansion of the film are measured,
the relative dielectric constant is not more than 3.5, the dielectric loss tangent is not more than 0.0100, and the coefficient of thermal expansion is not more than 80 ppm/K.

33. The antenna substrate material according to claim 1, wherein
when a film is produced using the antenna substrate material, and a relative dielectric constant and dielectric loss tangent of the film at frequencies of 10 GHz and 100 GHz are measured,
each relative dielectric constant is not more than 3.5, and each dielectric loss tangent is not more than 0.0100.

34. A method for manufacturing the antenna substrate material according to claim 1, the method comprising:
obtaining a polyimide (PI) using a diamine or diisocyanate and a tetracarboxylic dianhydride,
obtaining a polyamic acid (PA) using a diamine and a tetracarboxylic dianhydride, and
obtaining a block copolymer using the polyimide (PI) and the polyamic acid (PA).

35. An antenna substrate material composition comprising the antenna substrate material according to claim 1, and a solvent.
